(19) United States
(12) Patent Application Publication
(10) Pub. No.: US 2026/0304872 A1
(43) Pub. Date: Oct. 1, 2026

(54) SEMICONDUCTOR DEVICES HAVING ALTERNATING LAYERS OF TWO-DIMENSIONAL SEMICONDUCTOR MATERIAL AND METAL

(71) Applicant: SAMSUNG ELECTRONICS CO., LTD., Suwon-si (KR)

(72) Inventors: Sungnam LYU, Suwon-si (KR); Dongju KIM, Suwon-si (KR); Dosun LEE, Suwon-si (KR); Jongwon LEE, Suwon-si (KR)

(73) Assignee: SAMSUNG ELECTRONICS CO., LTD., Suwon-si (KR)

(21) Appl. No.: 19/570,877

(22) Filed: Mar. 18, 2026

(30) Foreign Application Priority Data
Mar. 31, 2025 (KR) 10-2025-0041405

(51) Int. Cl. H10D 62/17; H10D 30/47; H10D 64/62

(52) U.S. Cl. CPC H10D 62/292; H10D 30/481; H10D 64/62

(57) ABSTRACT

A semiconductor device includes a channel structure, and source and drain contact structures. The channel structure includes a two-dimensional semiconductor material. The channel structure includes a central portion extending in a first direction, and first and second extension portions. The first extension portions are disposed in a vertical direction, and each of the first extension portions extends in the first direction from a first end of the central portion. The second extension portions are disposed in the vertical direction, and each of the second extension portions extends in the first direction from a second end of the central portion. The source contact structure covers lower and upper surfaces and a sidewall of each of the first extension portions of the channel structure. The drain contact structure covers lower and upper surfaces and a sidewall of each of the second extension portions of the channel structure.

### CROSS-REFERENCE TO RELATED APPLICATION

This application claims priority under 35 USC § 119 to Korean Patent Application No. 10-2025-0041405, filed on MAR 31, 2025 in the Korean Intellectual Property Office (KIPO), the contents of which are herein incorporated by reference in their entirety.

### BACKGROUND

### Field

Embodiments of the present disclosure relate to semiconductor devices.

### Description of the Related Art

A two-dimensional semiconductor material has very few or no dangling bonds on its basal plane, resulting in excellent charge carrier mobility. Thus, research on using two-dimensional semiconductor material as a channel material has been actively conducted. However, when a metal of a source/drain contact contacts a two-dimensional semiconductor material of the channel a van der Waals gap is formed therebetween, which leads to a problem of very high contact resistance.

### SUMMARY

Embodiments of the present disclosure provide a semiconductor device having enhanced characteristics.

According to an embodiment, a semiconductor device may include a channel structure, a source contact structure and a drain contact structure. The channel structure may be disposed on a substrate and may include a two-dimensional semiconductor material. The channel structure may include a central portion extending in a first direction parallel to an upper surface of the substrate, first extension portions and second extension portions. The first extension portions may be spaced apart from each other in a vertical direction perpendicular to the upper surface of the substrate, and each of the first extension portions may extend in the first direction from a first end in the first direction of the central portion. The second extension portions may be spaced apart from each other in the vertical direction, and each of the second extension portions may extend in the first direction from a second end in the first direction of the central portion. The source contact structure may cover lower and upper surfaces and a sidewall of each of the first extension portions of the channel structure. The drain contact structure may cover lower and upper surfaces and a sidewall of each of the second extension portions of the channel structure.

According to an embodiment, a semiconductor device may include a first channel pattern, a first source contact pattern, a first drain contact pattern, a second channel pattern, a second source contact pattern and a second drain contact pattern. The first channel pattern may be disposed on a substrate. The first source contact pattern and the first drain contact pattern may cover upper surfaces of first and second ends, respectively, of the first channel pattern in a first direction parallel to an upper surface of the substrate. The second channel pattern may cover an upper surface and a sidewall of the first source contact pattern, and upper surface of a central portion in the first direction of the first channel pattern, and an upper surface and a sidewall of the first drain contact pattern. The second source contact pattern and the second drain contact pattern may cover upper surfaces of first and second ends, respectively, of the second channel pattern in the first direction. Each of the first and second channel patterns may include a two-dimensional semiconductor material.

According to an embodiment, a semiconductor device may include channel structures, a gate structure, a source contact structure and a drain contact structure. The channel structures may be disposed on a substrate and may be spaced apart from each other in a vertical direction perpendicular to an upper surface of the substrate. Each of the channel structures may include a two-dimensional semiconductor material and may include a central portion in a first direction parallel to the upper surface of the substrate, first extension portions and second extension portions. The first extension portions may be spaced apart from each other in the vertical direction, and each of the first extension portions may extend in the first direction from a first end in the first direction of the central portion. The second extension portions may be spaced apart from each other in the vertical direction, and each of the second extension portions may extend in the first direction from a second end in the first direction of the central portion. The gate structure may be disposed on the substrate and may extend in a second direction parallel to the upper surface of the substrate and crossing the first direction. The gate structure may at least partially cover the central portion of each of the channel structures. The source contact structure may cover lower and upper surfaces and a sidewall of each of the first extension portions of each of the channel structures. The drain contact structure may cover lower and upper surfaces and a sidewall of each of the second extension portions of each of the channel structures. A first channel structure among the channel structures may include a first central portion, first-1 extension portions and second-1 extension portions. Each of the first-1 extension portions may extend in the first direction from a first end in the first direction of the first central portion. Each of the second-1 extension portions may extend in the first direction from a second end in the first direction of the first central portion.

In a semiconductor device in accordance with an embodiment, the channel including a two-dimensional semiconductor material may include the central portion, the first extension portions at the first end of the central portion and spaced apart from each other in the vertical direction, and the second extension portions at the second end of the central portion and spaced apart from each other in the vertical direction. The source and drain contact structures may cover the lower and upper surfaces and the sidewalls of the first and second extension portions, respectively, and thus a contact area between the channel and the source and drain contact structures may increase so as to reduce a contact resistance therebetween.

### BRIEF DESCRIPTION OF THE DRAWINGS

FIG. 1 is a cross-sectional view illustrating a semiconductor device in accordance with an embodiment.

FIGS. 2-6 are cross-sectional views illustrating a method of manufacturing a semiconductor device in accordance with an embodiment.

FIG. 7 is a cross-sectional view illustrating a semiconductor device in accordance with an embodiment.

FIGS. 8 and 9 are cross-sectional views illustrating a method of manufacturing a semiconductor device in accordance with an embodiment.

FIG. 10 is a cross-sectional view illustrating a semiconductor device in accordance with an embodiment.

FIG. 11 is a cross-sectional view illustrating a semiconductor device in accordance with an embodiment.

FIGS. 12-14 are a perspective view, a partial exploded perspective view, and a cross-sectional view illustrating a semiconductor device in accordance with an embodiment.

FIGS. 15-29 are perspective and cross-sectional views illustrating a method of manufacturing a semiconductor device in accordance with an embodiment.

FIGS. 30-32 are cross-sectional views illustrating a method of manufacturing a semiconductor device in accordance with an embodiment.

### DESCRIPTION OF EMBODIMENTS

Hereinafter, a semiconductor device and a method for manufacturing the same in accordance with embodiments of the present disclosure will be described in detail with reference to the accompanying drawings. It will be understood that, although the terms “first,” “second,” and/or “third” may be used herein to describe various elements, these elements should not be limited by these terms. These terms are only used to distinguish one element from another element.

Two directions intersecting each other among horizontal directions that are substantially parallel to an upper surface of a substrate may be referred to as first and second directions D1 and D2, respectively, and a vertical direction that is substantially perpendicular to the upper surface of the substrate may be referred to as a third direction D3.

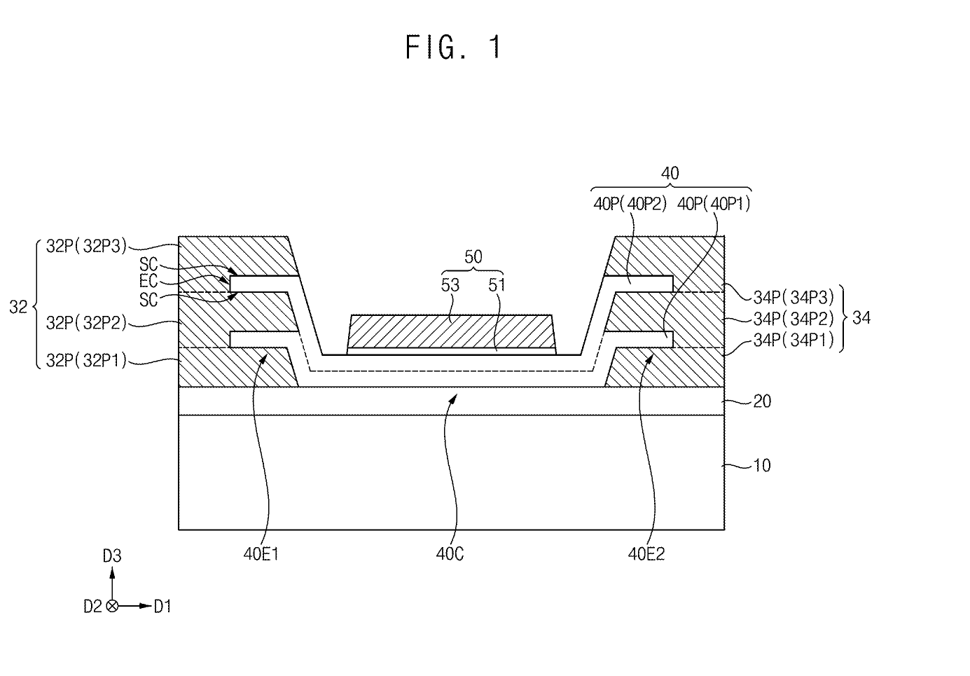

FIG. 1 is a cross-sectional view illustrating a semiconductor device in accordance with an embodiment.

Referring to FIG. 1, the semiconductor device may include a substrate 10, an insulation layer 20, a source contact structure 32, a drain contact structure 34, a channel structure 40, and a gate structure 50.

The substrate 10 may include a semiconductor material, e.g., silicon, germanium, silicon-germanium, or the like, or a III-V group compound semiconductor, e.g., GaP, GaAs, GaSb, or the like. In an embodiment, the substrate 10 may be a silicon-on-insulator (SOI) substrate or a germanium-on-insulator (GOI) substrate.

The insulation layer 20 may be disposed on an upper surface of the substrate 10. The insulation layer 20 may at least partially cover the upper surface of the substrate 10. The insulation layer 20 may include, e.g., silicon nitride, silicon oxynitride, silicon oxycarbide, silicon boronitride, silicon boron carbonitride, silicon oxycarbonitride, or the like.

The source contact structure 32 may include a plurality of source contact patterns 32P sequentially stacked on the insulation layer 20 in the third direction D3.

The drain contact structure 34 may include a plurality of drain contact patterns 34P sequentially stacked on the substrate 10 in the third direction D3.

Each of the source contact structure 32 and the drain contact structure 34 may include, e.g., gold, palladium, niobium, nickel, cobalt, scandium, yttrium, vanadium, hafnium, zirconium, tantalum, aluminum, indium, copper, zinc, or the like.

The channel structure 40 may include a plurality of channel patterns 40P sequentially stacked on the insulation layer 20 in the third direction D3. In an embodiment, the channel structure 40 may include two to nine channel patterns 40P, preferably, two or three channel patterns 40P.

In an embodiment, the channel structure 40 may include two to nine two-dimensional semiconductor material layers. Electrical and optical properties of two-dimensional semiconductor materials vary significantly depending on the number of layers. Generally, the unique characteristics of the two-dimensional semiconductor materials are most pronounced in monolayer or few-layer forms. For example, in case of transition metal dichalcogenides (TMDs) such as MoS₂, WS₂, a monolayer exhibits a direct bandgap, whereas from a bilayer onward, an indirect bandgap characteristic begins to appear. As the number of layers increases, the properties of the two-dimensional semiconductor material gradually approach those of bulk material, and generally, when the number of layers exceeds approximately ten, most two-dimensional characteristics are lost and bulk-like properties are exhibited.

The channel structure 40 may include a two-dimensional semiconductor material. The two-dimensional semiconductor material may include, e.g., graphene, carbon nanotube, transition metal dichalcogenide (TMD), or the like. The TMD may include at least one of a metal such as Mo, W, Nb, V, Ta, Ti, Zr, Hf, Tc, Re, Cu, Ga, In, Sn, Ge, or Pb, and one of a chalcogenide such as S, Se, Te, or the like. The TMD may include, e.g., MoS₂, MoTe₂, MoSe₂, WS₂, Wse₂, WTe₂, or the like.

In an embodiment, each of the channel patterns 40P may include a monolayer or a multilayer of the two-dimensional material. In an embodiment, each of the channel patterns 40P may include TMD.

The channel structure 40 may include a central portion 40C, first extension portions 40E1 and second extension portions 40E2. The central portion 40C may extend in the first direction D1 on the insulation layer 20. Each of the first extension portions 40E1 may extend in the first direction D1 from a first end in the first direction D1 of the central portion 40C, and the first extension portions 40E1 may be spaced apart from each other in the third direction D3. Each of the second extension portions 40E2 may extend in the first direction D1 from a second end in the first direction D1, which is opposite to the first end, of the central portion 40C, and the second extension portions 40E2 may be spaced apart from each other in the third direction D3.

In an embodiment, the channel structure 40 may include two to nine first extension portions 40E1, preferably, two or three first extension portions 40E1. In an embodiment, the channel structure 40 may include two to nine second extension portions 40E2, preferably, two or three second extension portions 40E2.

The source contact structure 32 may cover lower and upper surfaces and a sidewall of each of the first extension portions 40E1, and the drain contact structure 34 may cover lower and upper surfaces and a sidewall of each of the second extension portions 40E2.

In an embodiment, an upper surface of an uppermost one of the first extension portions 40E1 of the channel structure 40 and an upper surface of an uppermost one of the second extension portions 40E2 of the channel structure 40 may be higher than an upper surface of the central portion 40C of the channel structure 40. In an embodiment, a lower surface of a lowermost one of the first extension portions 40E1 of the channel structure 40 and a lower surface of a lowermost one of the second extension portions 40E2 of the channel structure 40 may be higher than a lower surface of the central portion 40C of the channel structure 40.

In an embodiment, the first extension portions 40E1 of the channel structure 40 may be disposed at substantially the same level as the second extension portions 40E2, respectively, of the channel structure 40.

Each of the first extension portions 40E1 of the channel structure 40 may have a first thickness T1 in the third direction D3, each of the second extension portions 40E2 of the channel structure 40 may have a second thickness T2 in the third direction D3, and the central portion 40C of the channel structure 40 may have a third thickness T3 in the third direction D3. In an embodiment, the third thickness T3 may be greater than the first thickness T1. In an embodiment, the third thickness T3 may be greater than the second thickness T2. In an embodiment, the first thickness T1 may be substantially the same as the second thickness T2.

FIG. 1 shows that three source contact patterns 32P are sequentially stacked on the insulation layer 20. Hereinafter, the three source contact patterns 32P sequentially stacked on the insulation layer 20 may be referred to as first, second and third source contact patterns 32P1, 32P2 and 32P3, respectively.

FIG. 1 shows that three drain contact patterns 34P are sequentially stacked on the insulation layer 20. Hereinafter, the three drain contact patterns 34P sequentially stacked on the insulation layer 20 may be referred to as first, second and third drain contact patterns 34P1, 34P2 and 34P3, respectively.

FIG. 1 shows that two channel patterns 40P are sequentially stacked on the insulation layer 20. Hereinafter, the two channel patterns 40P may be referred to as first and second channel patterns 40P1 and 40P2, respectively.

The first source contact pattern 32P1 and the first drain contact pattern 34P1 may be spaced apart from each other in the first direction D1 on the insulation layer 20. The first channel pattern 40P1 may cover an upper surface and a sidewall of the first source contact pattern 32P1, an upper surface of the insulation layer 20, and an upper surface and a sidewall of the first drain contact pattern 34P1. The second source contact pattern 32P2 and the second drain contact pattern 34P2 may cover upper surfaces of respective ends in the first direction D1 of the first channel pattern 40P1. The second channel pattern 40P2 may cover an upper surface and a sidewall of the second source contact pattern 32P2, an upper surface of a central portion in the first direction D1 of the first channel pattern 40P1, and a sidewall of the second drain contact pattern 34P2. The third source contact pattern 32P3 and the third drain contact pattern 34P3 may cover upper surfaces of respective ends in the first direction D1 of the second channel pattern 40P2.

In an embodiment, lower and upper surfaces and a sidewall of a first end in the first direction D1 of the first channel pattern 40P1 may be covered by the first and second source contact patterns 32P1 and 32P2, and lower and upper surfaces and a sidewall of a second end in the first direction D1, which is opposite to the first end, of the first channel pattern 40P1 may be covered by the first and second drain contact patterns 34P1 and 34P2. In an embodiment, lower and upper surfaces and a sidewall of a first end in the first direction D1 of the second channel pattern 40P2 may be covered by the second and third source contact patterns 32P2 and 32P3, and lower and upper surfaces and a sidewall of a second end in the first direction D1, which is opposite to the first end, of the second channel pattern 40P2 may be covered by the second and third drain contact patterns 34P2 and 34P3.

In an embodiment, the gate structure 50 may be disposed on an upper surface of the central portion 40C of the channel structure 40, that is, on an upper surface of a central portion of the second channel pattern 40P2. The gate structure 50 may include a gate insulation pattern 51 and a gate electrode 53 sequentially stacked in the third direction D3.

The gate insulation pattern 51 may include silicon oxide, a low-k dielectric material having a dielectric constant lower than that of silicon oxide, or a high-k dielectric material, e.g., hafnium oxide, zirconium, oxide, or the like. The gate electrode 53 may include a metal, e.g., titanium, platinum, ruthenium, gold, silver, molybdenum, aluminum, tungsten, copper, or the like, a conductive nitride, e.g., titanium nitride, tungsten nitride, tantalum nitride, or the like, or a conductive oxide, e.g., InZnO, AlZnO, or the like.

The two-dimensional semiconductor material has very few or no dangling bonds on its basal planes, and thus exhibit excellent charge carrier mobility. However, when a metal of a source/drain contact contacts a two-dimensional semiconductor material of the channel, a van der Waals gap is formed therebetween, which leads to a problem of very high contact resistance.

The channel structure 40 of the semiconductor device in accordance with an embodiment may include the central portion 40C, a plurality of first extension portions 40E1 and a plurality of second extension portions 40E2. The source contact structure 32 and the drain contact structure 34 may cover the lower and upper surfaces and the sidewalls of the first and second extension portions 40E1 and 40E2, and thus the channel structure 40 may have a plurality of surface contacts (SCs) and a plurality of edge contacts (ECs). Accordingly, a total contact area between the channel structure 40 and the source and drain contact structures 32 and 34 may increase so as to decrease a contact resistance.

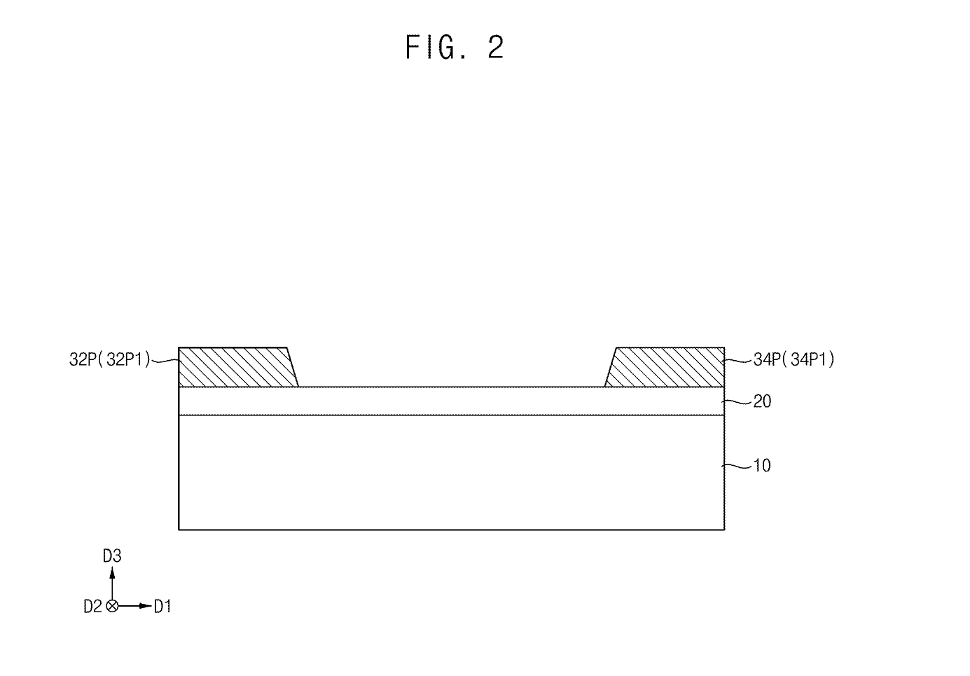

FIGS. 2-6 are cross-sectional views illustrating a method of manufacturing a semiconductor device in accordance with an embodiment.

Referring to FIG. 2, an insulation layer 20 may be formed on a substrate 10. The insulation layer 20 may at least partially cover an upper surface of the substrate 10.

A first metal layer may be formed on the insulation layer 20. The first metal layer may include e.g., gold, palladium, niobium, nickel, cobalt, scandium, yttrium, vanadium, hafnium, zirconium, tantalum, aluminum, indium, copper, zinc, or the like.

The first metal layer may be patterned. Thus, an upper surface of the insulation layer may be exposed, and the first metal layer may be divided into a first source contact pattern 32P1 and a first drain contact pattern 34P1 that are spaced apart from each other in the first direction D1.

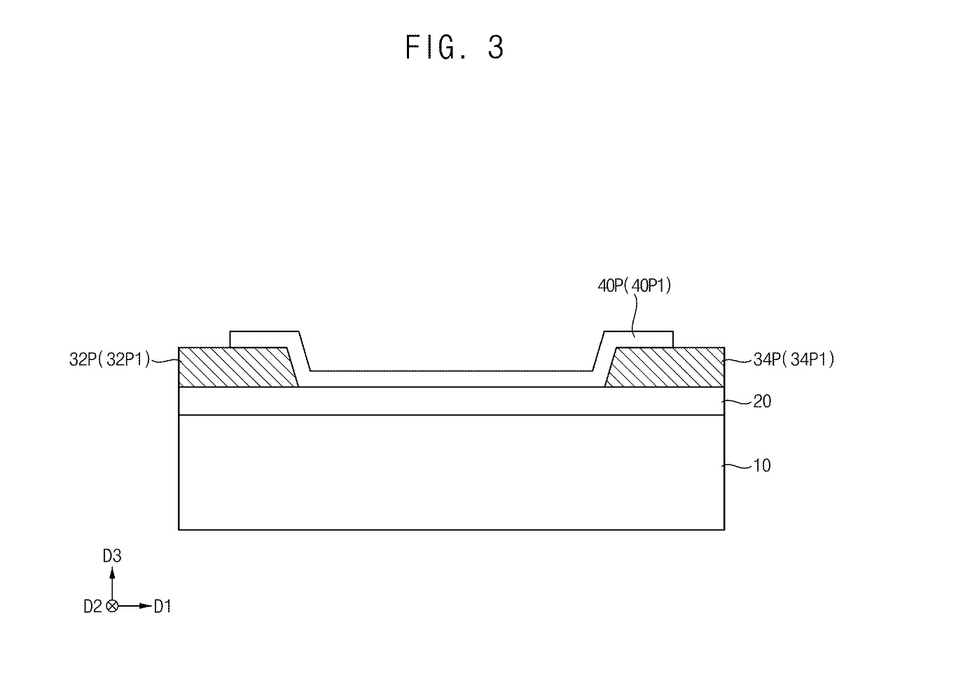

Referring to FIG. 3, a first channel pattern 40P1 may be formed on an upper surface and a sidewall of the first source contact pattern 32P1, the exposed upper surface of the insulation layer 20, and an upper surface and a sidewall of the first drain contact pattern 34P1.

The first channel pattern 40P1 may include, e.g., a two-dimensional semiconductor material. The two-dimensional semiconductor material may include, e.g., graphene, carbon nanotube, transition metal dichalcogenide (TMD), or the like.

The two-dimensional semiconductor material of the first channel pattern 40P1 may be formed by various methods. For example, the two-dimensional semiconductor material may be formed by a top-down method such as mechanical exfoliation, liquid-phase exfoliation or electrochemical exfoliation, or a bottom-up method such as chemical vapor deposition (CVD), molecular beam epitaxy (MBE) or atomic layer deposition (ALD), or the like. The two-dimensional semiconductor material may be transferred to a target substrate by various methods. For example, the two-dimensional semiconductor material may be transferred by a wet transfer method such as a PMMA-assisted transfer method or a bubble transfer method, a dry transfer method such as a PDMS-based direct dry transfer method or a stamp transfer method, a roll-to-roll transfer method suitable for large-area processing, or a pick-and-place method capable of precise placement. The selection of the transfer method may be determined depending on a target application, a desired interfacial quality, and a production scale.

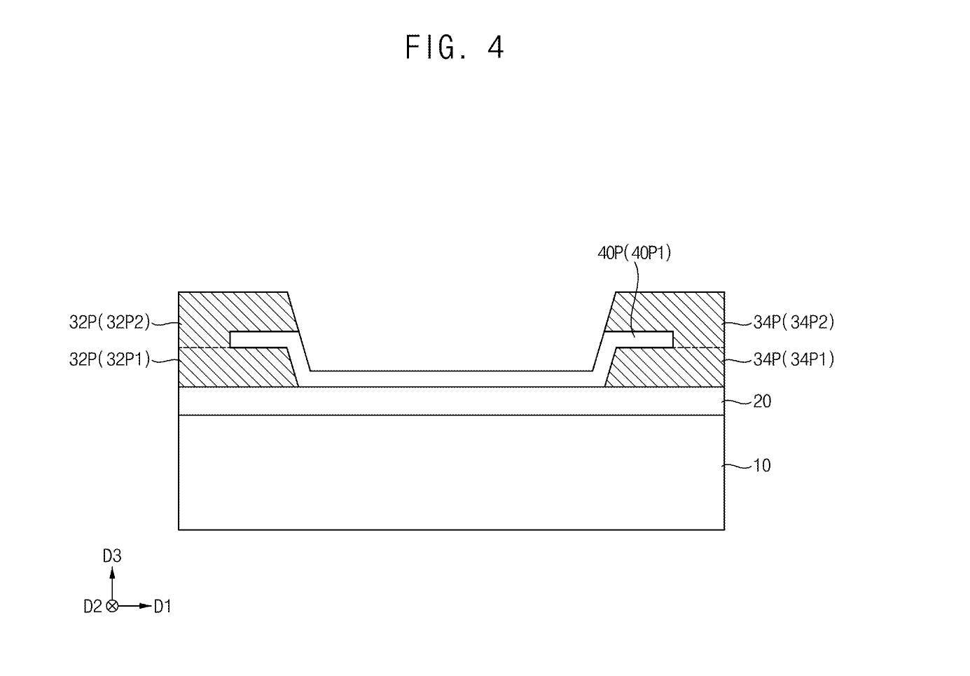

Referring to FIG. 4, a second metal layer may be formed on the first source contact pattern 32P1, the first channel pattern 40P1 and the first drain contact pattern 34P1. The second metal layer may include, e.g., gold, palladium, niobium, nickel, cobalt, scandium, yttrium, vanadium, hafnium, zirconium, tantalum, aluminum, indium, copper, zinc, or the like. In an embodiment, the second metal layer may include substantially the same material as the first metal layer.

The second metal layer may be patterned. Thus, an upper surface of the first channel pattern 40P1 may be exposed, and the second metal layer may be divided into a second source contact pattern 32P2 and a second drain contact pattern 34P2 that are spaced apart from each other in the first direction D1. In an embodiment, the second source contact pattern 32P2 may cover an upper surface of the first source contact pattern 32P1 and an upper surface and a sidewall of a first end in the first direction D1 of the first channel pattern 40P1. In an embodiment, the second drain contact pattern 34P2 may cover an upper surface of the first drain contact pattern 34P1 and an upper surface and a sidewall of a second end in the first direction D1 that are opposite to the first end, of the first channel pattern 40P1.

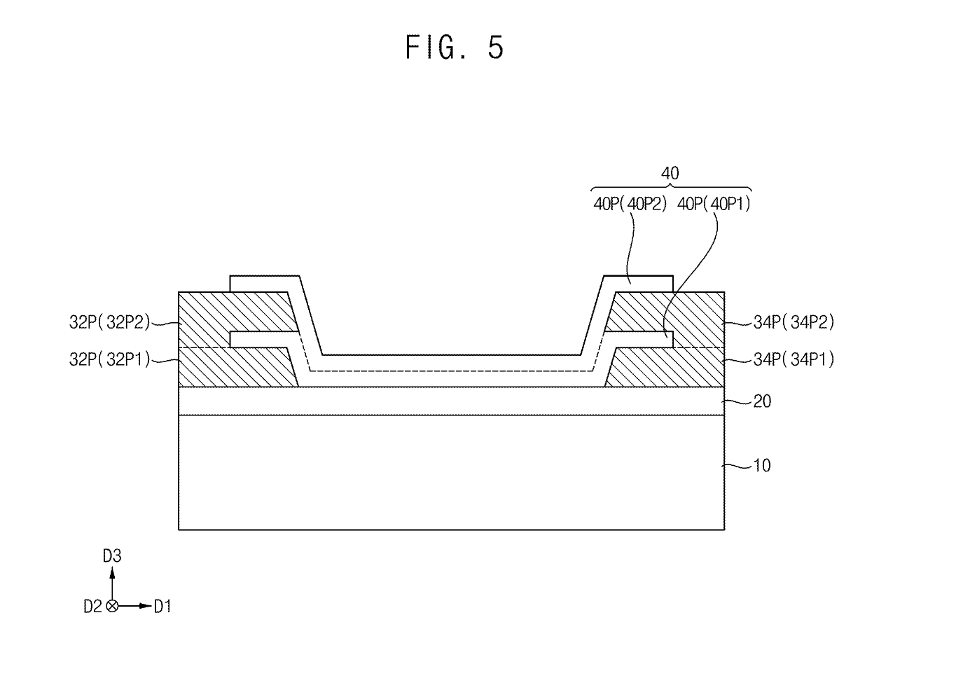

Referring to FIG. 5, a second channel pattern 40P2 may be formed on an upper surface and a sidewall of the second source contact pattern 32P2, the exposed upper surface of the first channel pattern 40P1, and an upper surface and a sidewall of the second drain contact pattern 34P2.

The second channel pattern 40P2 may include, e.g., a two-dimensional semiconductor material. The two-dimensional semiconductor material may include, e.g., graphene, carbon nanotube, transition metal dichalcogenide (TMD), or the like. In an embodiment, the second channel pattern 40P2 may include substantially the same material as the first channel pattern 40P1.

The two-dimensional semiconductor material of the second channel pattern 40P2 may be formed or transferred to a target substrate by methods substantially the same as or similar to those of forming the two-dimensional semiconductor material of the first channel pattern 40P1.

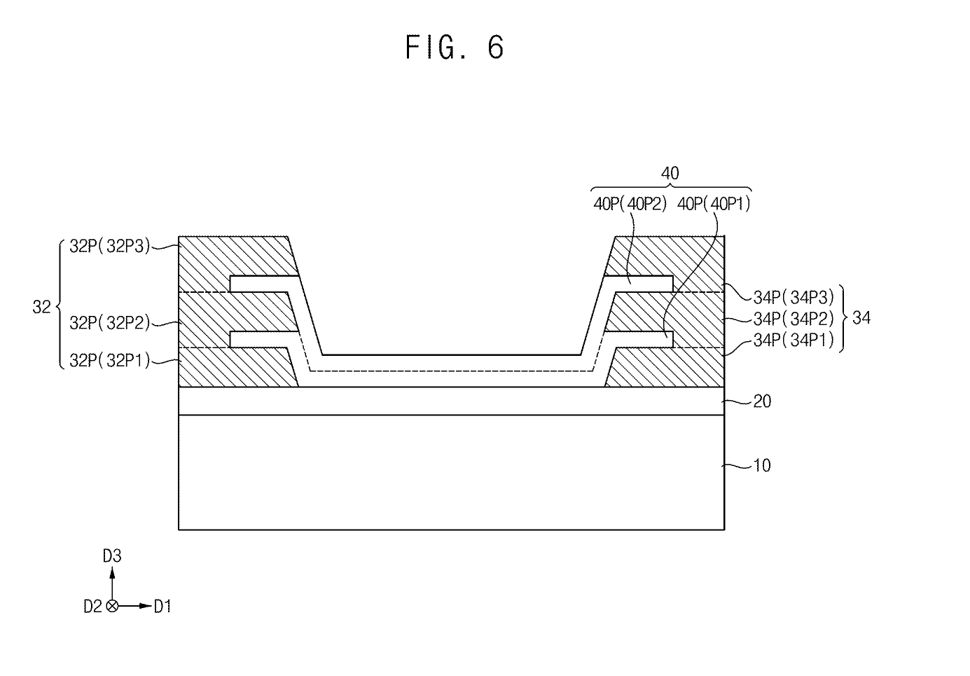

Referring to FIG. 6, a third metal layer may be formed on the second source contact pattern 32P2, the second channel pattern 40P2 and the second drain contact pattern 34P2. The third metal layer may include, e.g., gold, palladium, niobium, nickel, cobalt, scandium, yttrium, vanadium, hafnium, zirconium, tantalum, aluminum, indium, copper, zinc, or the like. In an embodiment, the third metal layer may include substantially the same material as the first and second metal layers.

The third metal layer may be patterned. Thus, an upper surface of the second channel pattern 40P2 may be exposed, and the third metal layer may be divided into a third source contact pattern 32P3 and a third drain contact pattern 34P3 that are spaced apart from each other in the first direction D1. In an embodiment, the third source contact pattern 32P3 may cover an upper surface of the second source contact pattern 32P2 and an upper surface and a sidewall of a first end in the first direction D1 of the second channel pattern 40P2. In an embodiment, the third drain contact pattern 34P3 may cover an upper surface of the second drain contact pattern 34P2 and an upper surface and a sidewall of a second end in the first direction D1 that are opposite to the first end, of the second channel pattern 40P2.

The first to third source contact patterns 32P1, 32P2 and 32P3 may form a source contact structure 32. The first to third drain contact patterns 34P1, 34P2 and 34P3 may form a drain contact structure 34. The first and second channel patterns 40P1 and 40P2 may form a channel structure 40.

Referring to FIG. 1 again, a gate structure 50 including a gate insulation pattern 51 and a gate electrode 53 sequentially stacked on the upper surface of the second channel pattern 40P2 may be formed to complete the fabrication of the semiconductor device.

In the method of manufacturing the semiconductor device, the source and drain contact patterns 32P and 34P and the channel patterns 40P may be alternately formed. Thus, a contact area between the source and drain contact structures 32 and 34 and the channel structure 40 may increase, so as to reduce a contact resistance therebetween.

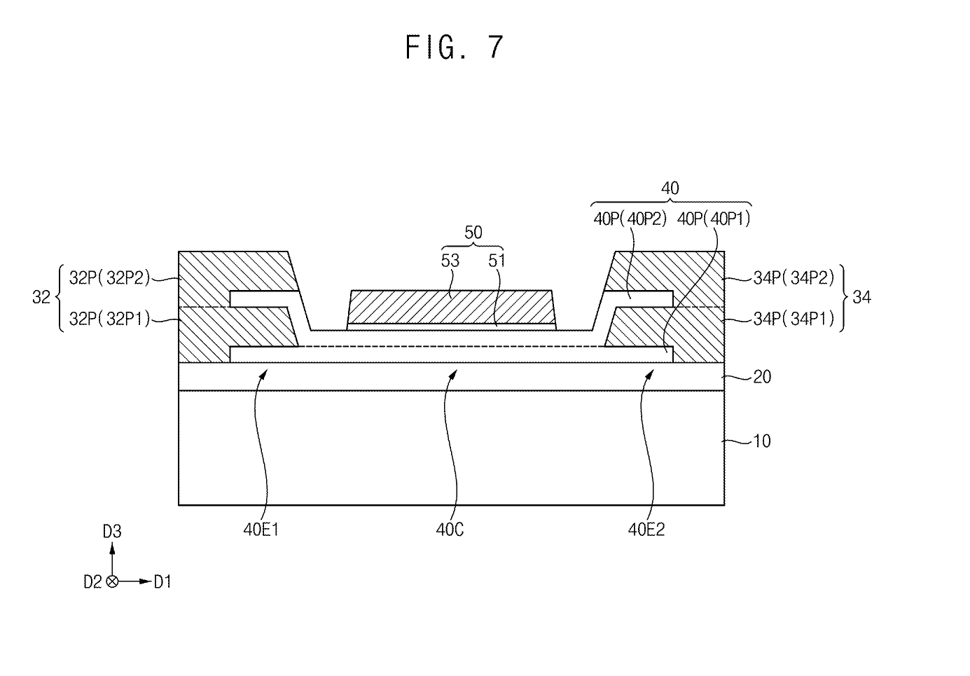

FIG. 7 is a cross-sectional view illustrating a semiconductor device in accordance with an embodiment.

An embodiment of a semiconductor device according to FIG. 7 may be substantially the same as or similar to that of FIG. 1, except for the shape of the source contact structure 32, the number of the source contact patterns 32P, the shape of the drain contact structure 34, the number of the drain contact patterns 34P, and the shape of the channel structure 40. Thus, repeated explanations are omitted herein.

Referring to FIG. 7, in an embodiment, the lower surface of the lowermost one of the first extension portions 40E1 of the channel structure 40 and the lower surface of the lowermost one of the second extension portions 40E2 of the channel structure 40 may be substantially coplanar with the lower surface of the central portion 40C of the channel structure 40.

FIG. 7 shows that two source contact patterns 32P are stacked on the insulation layer 20. The two source contact patterns 32P may be referred as first and second source contact patterns 32P1 and 32P2, respectively. FIG. 7 shows that two drain contact patterns 34P are stacked on the insulation layer 20. The two drain contact patterns 34P may be referred as first and second source contact patterns 34P1 and 34P2, respectively.

The first channel pattern 40P1 may cover the upper surface of the insulation layer 20. The first source contact pattern 32P1 and the first drain contact pattern 34P1 may cover the upper surfaces of the first and second ends in the first direction D1 of the first channel pattern 40P1. The second channel pattern 40P2 may cover the upper surface and the sidewall of the first source contact pattern 32P1, the upper surface of the central portion in the first direction D1 of the first channel pattern 40P1, and the upper surface and the sidewall of the first drain contact pattern 34P1. The second source contact pattern 32P2 and the second drain contact pattern 34P2 may cover the upper surfaces of respective ends in the first direction D1 of the second channel pattern 40P2.

In an embodiment, the upper surface and the sidewall of the first end in the first direction D1 of the first channel pattern 40P1 may be covered by the first source contact pattern 32P1, and the upper surface and the sidewall of the second end in the first direction D1, which is opposite to the first end, of the first channel pattern 40P1 may be covered by the first drain contact pattern 34P1. In an embodiment, the lower and upper surfaces and the sidewall of the first end in the first direction D1 of the second channel pattern 40P2 may be covered by the first and second source contact patterns 32P1 and 32P2, and the lower and upper surfaces and the sidewall of the second end in the first direction D1, which is opposite to the first end, of the second channel pattern 40P2 may be covered by the first and second drain contact patterns 34P1 and 34P2.

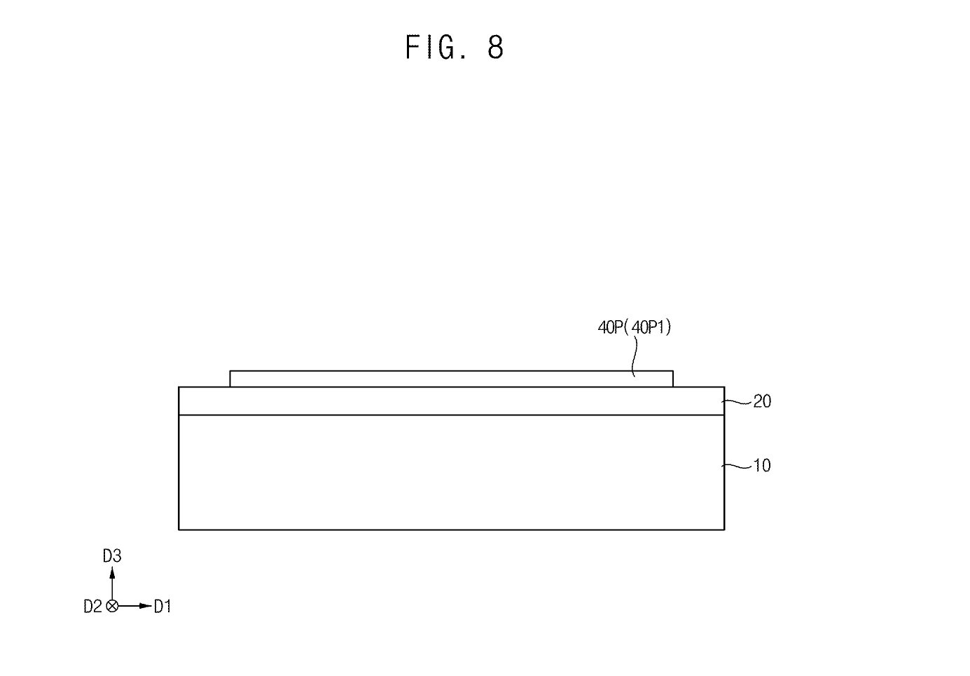

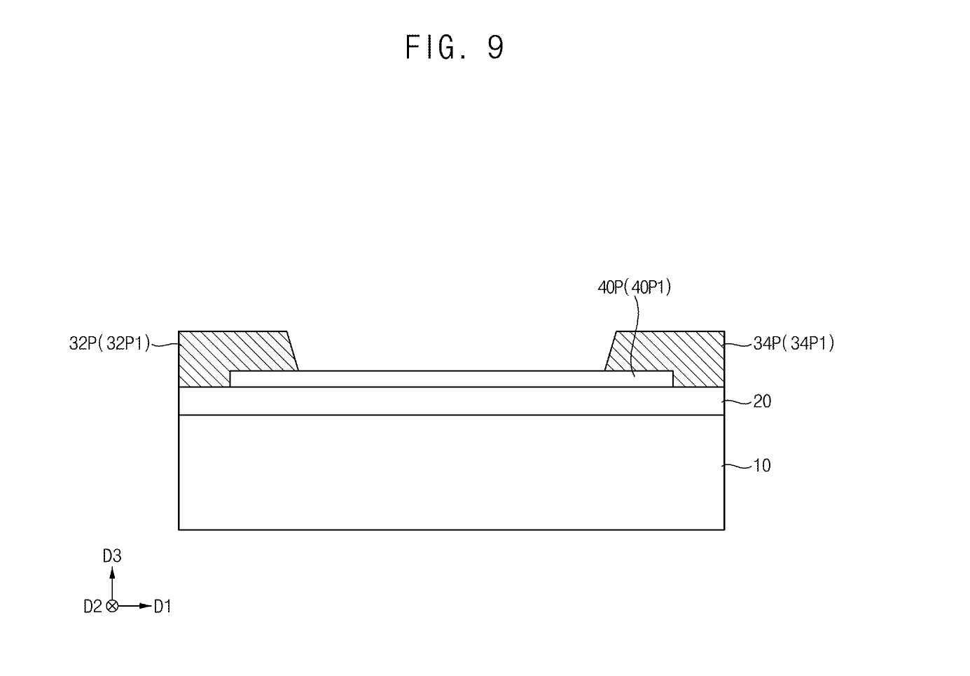

FIGS. 8 and 9 are cross-sectional views illustrating a method of manufacturing a semiconductor device in accordance with an embodiment, which may correspond to FIGS. 2 and 3, respectively. This method may include processes substantially the same as or similar to those illustrated with reference to FIGS. 2-6 and 1, and thus repeated explanations thereof are omitted herein.

Referring to FIGS. 8 and 9, unlike those of FIGS. 2 and 3, after forming the first channel pattern 40P1 on the insulation layer 20, the first source contact pattern 32P1 and the first drain contact pattern 34P1 may be formed on the first and second ends, respectively, in the first direction D1 of the first channel pattern 40P1.

Processes substantially the same as or similar to those illustrated with reference to FIGS. 5 and 6 and FIG. 1 may be performed to complete the fabrication of the semiconductor device.

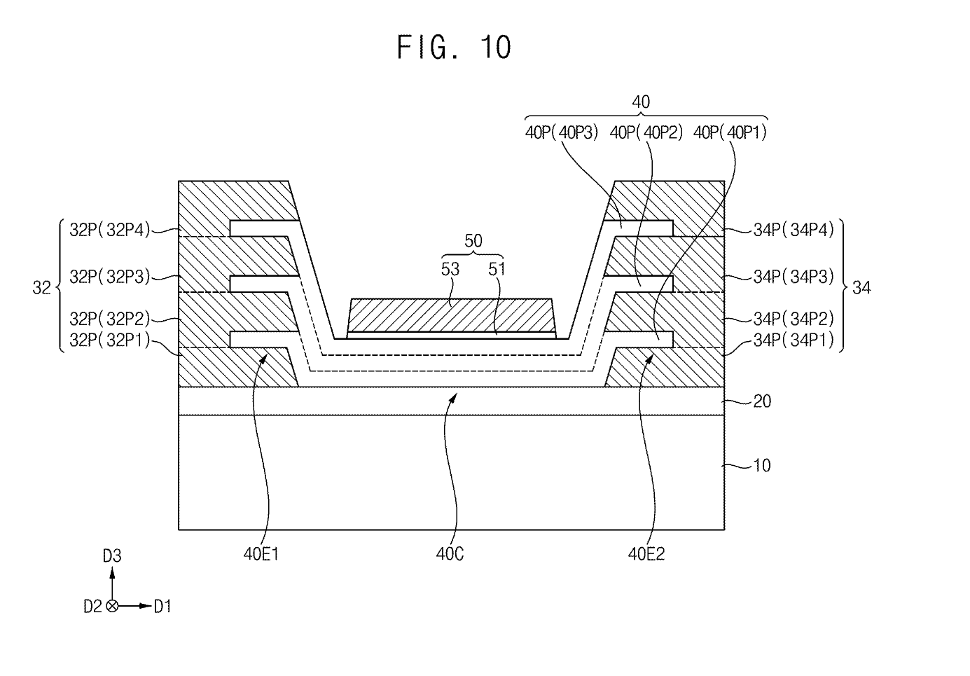

FIG. 10 is a cross-sectional view illustrating a semiconductor device in accordance with an embodiment, which may correspond to FIG. 1.

An embodiment of a semiconductor device according to FIG. 10 may be substantially the same as or similar to that of FIG. 1, except for the number of the source contact patterns 32P included in the source contact structure 32, the number of the drain contact patterns 34P included in the drain contact structure 34, and the number of the channel patterns 40P included in the channel structure 40. Thus, repeated explanations are omitted herein.

Referring to FIG. 10, unlike those of the semiconductor device shown in FIG. 1, the source contact structure 32 may include four source contact patterns 32P sequentially stacked on the insulation layer 20, the drain contact structure 34 m ay include four drain contact patterns 34P sequentially stacked on the insulation layer 20, and the channel structure 40 may include three channel patterns 40P sequentially stacked on the insulation layer 20.

In FIG. 10, when compared to those of FIG. 1, the source contact structure 32 may further include a fourth source contact pattern 32P4, the drain contact structure 34 may further include a fourth drain contact pattern 34P4, and the channel structure 40 may further include a third channel pattern 40P3.

The third channel pattern 40P3 may cover an upper surface and a sidewall of the third source contact pattern 32P3, an upper surface of a central portion in the first direction D1 of the second channel pattern 40P2, and an upper surface and a sidewall of the third drain contact pattern 34P3. The fourth source contact pattern 32P4 and the fourth drain contact pattern 34P4 may cover upper surfaces of ends in the first direction D1 of the third channel pattern 40P3.

In an embodiment, lower and upper surfaces and a sidewall of a first end in the first direction D1 of the third channel pattern 40P3 may be covered by the third and fourth source contact patterns 32P3 and 32P4, and lower and upper surfaces and a sidewall of a second end in the first direction D1 of the third channel pattern 40P3 may be covered by the third and fourth drain contact patterns 34P3 and 34P4.

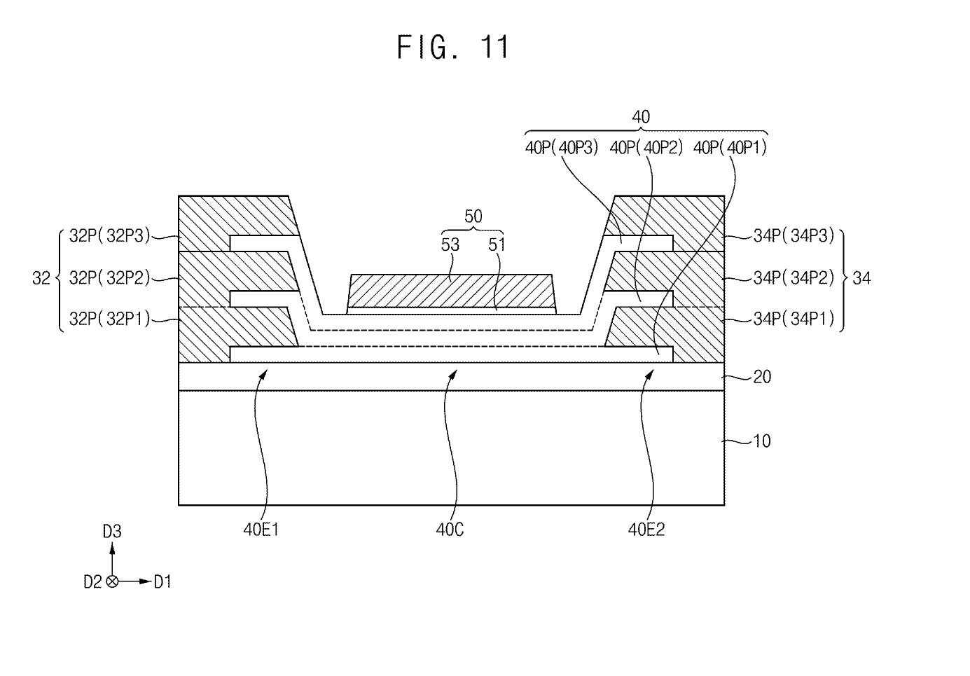

FIG. 11 is a cross-sectional view illustrating a semiconductor device in accordance with an embodiment, which may correspond to FIG. 7.

An embodiment of a semiconductor device according to FIG. 11 may be substantially the same as or similar to that of FIG. 7, except for the number of the source contact patterns 32P included in the source contact structure 32, the number of the drain contact patterns 34P included in the drain contact structure 34, and the number of the channel patterns 40P included in the channel structure 40. Thus, repeated explanations are omitted herein.

Referring to FIG. 11, unlike those of the semiconductor device shown in FIG. 7, the source contact structure 32 may include three source contact patterns 32P sequentially stacked on the insulation layer 20, the drain contact structure 34 m ay include three drain contact patterns 34P sequentially stacked on the insulation layer 20, and the channel structure 40 may include three channel patterns 40P sequentially stacked on the insulation layer 20.

In FIG. 11, when compared to those of FIG. 7, the source contact structure 32 may further include the third source contact pattern 32P3, the drain contact structure 34 may further include the third drain contact pattern 34P3, and the channel structure 40 may further include the third channel pattern 40P3.

The third channel pattern 40P3 may cover the upper surface and the sidewall of the second source contact pattern 32P2, the upper surface of the central portion in the first direction D1 of the second channel pattern 40P2, and the upper surface and the sidewall of the second drain contact pattern 34P2. The third source contact pattern 32P3 and the third drain contact pattern 34P3 may cover the upper surfaces of the ends in the first direction D1 of the third channel pattern 40P3.

In an embodiment, the lower and upper surfaces and the sidewall of the first end in the first direction D1 of the third channel pattern 40P3 may be covered by the second and third source contact patterns 32P2 and 32P3, and the lower and upper surfaces and the sidewall of the second end in the first direction D1 of the third channel pattern 40P3 may be covered by the second and third drain contact patterns 34P2 and 34P3.

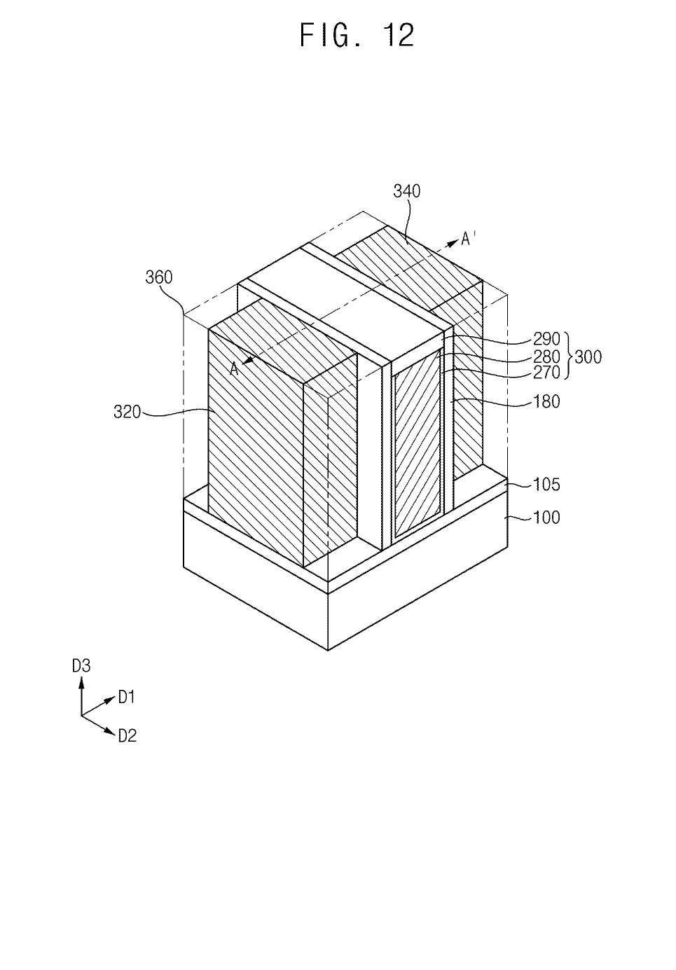

FIGS. 12-14 are a perspective view, a partial exploded perspective view and a cross-sectional view illustrating a semiconductor device in accordance with an embodiment.

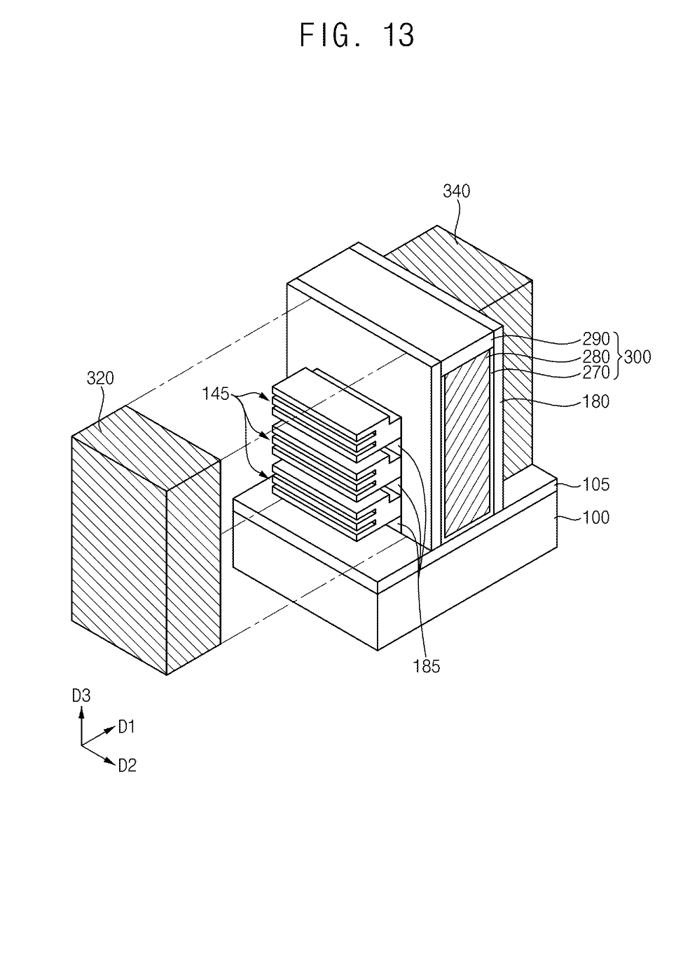

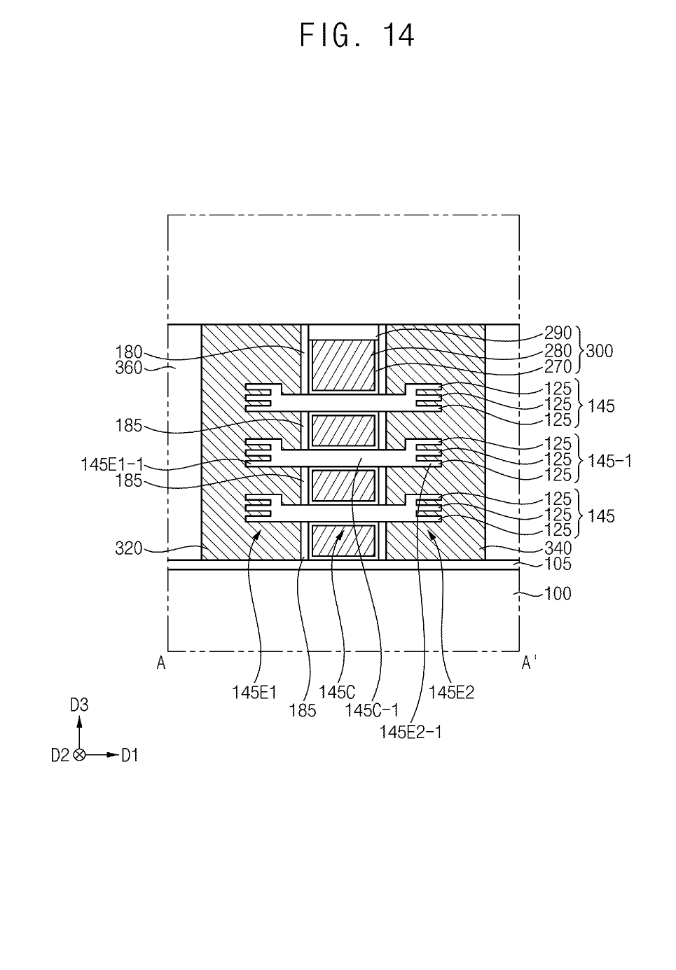

Particularly, FIG. 12 is the perspective view, FIG. 13 is the partial exploded perspective view, and FIG. 14 is a cross-sectional view taken along line A-A’ of FIG. 12.

An embodiment of a semiconductor device according to FIGS. 12-14 may be an application of the channel structure 40 illustrated with reference to FIG. 11 to a gate-all-around (GAA) transistor, and repeated explanations are omitted herein. An embodiment of a semiconductor device according to FIGS. 12-14 may include one of the channel structures 40 shown in FIGS. 1, 7 and 10.

Referring to FIGS. 12-14, the semiconductor device may include a substrate 100, an insulation layer 105, a channel structure 145, a gate structure 300, a first gate spacer 180, a second gate spacer 185, a source contact structure 320, a drain contact structure 340 and an insulating interlayer 360.

The substrate 100 may include a semiconductor material, e.g., silicon, germanium, silicon-germanium, or the like, or a III-V group compound semiconductor, e.g., GaP, GaAs, GaSb, or the like. In an embodiment, the substrate 100 may be a silicon-on-insulator (SOI) substrate or a germanium-on-insulator (GOI) substrate.

The insulation layer 105 may be disposed on an upper surface of the substrate 100. The insulation layer 105 may at least partially cover the upper surface of the substrate 100. The insulation layer 105 may include, e.g., silicon nitride, silicon oxynitride, silicon oxycarbide, silicon boronitride, silicon boron carbonitride, silicon oxycarbonitride, or the like.

In an embodiment, a plurality of channel structures 145 may be spaced apart from each other in the third direction D3 on the substrate 100.

The channel structure 145 may include a central portion 145C, first extension portions 145E1 and second extension portions 145E2. The central portion 145C may extend in the first direction D1, and the central portions 145C of the respective channel structures 145 may be spaced apart from each other in the third direction D3. Each of the first extension portions 145E1 may extend in the first direction D1 from a first end in the first direction D1 of the central portion 145C, and the first extension portions 145E1 may be spaced apart from each other in the third direction D3. Each of the second extension portions 145E2 may extend in the first direction D1 from a second end in the first direction D1, which is opposite to the first end, of the central portion 145C, and the second extension portions 145E2 may be spaced apart from each other in the third direction D3.

A first channel structure 145-1 of the channel structures 145 may include a first central portion 145C-1 among the central portions 145C, a plurality of first-1 extension portions 145E1-1 among the first extension portions 145E1 extending in the first direction D1 from a first end in the first direction D1 of the first central portion 145C-1, and a plurality of second-1 extension portions 145E2-1 among the second extension portions 145E2 extending in the first direction D1 from a second end in the first direction D1 of the first central portion 145C-1.

In an embodiment, an upper surface of an uppermost one of the first-1 extension portions 145E1-1 of the first channel structure 145-1 and an upper surface of an uppermost one of the second-1 extension portions 145E2-1 of the first channel structure 145-1 may be higher than an upper surface of the first central portion 145C-1 of the first channel structure 145-1.

In an embodiment, a lower surface of a lowermost one of the first-1 extension portions 145E1-1 of the first channel structure 145-1 and a lower surface of a lowermost one of the second-1 extension portions 145E2-1 of the first channel structure 145-1 may be substantially coplanar with a lower surface of the first central portion 145C-1 of the first channel structure 145-1. Alternatively, the lower surface of the lowermost one of the first-1 extension portions 145E1-1 of the first channel structure 145-1 and the lower surface of the lowermost one of the second-1 extension portions 145E2-1 of the first channel structure 145-1 may be higher than the lower surface of the first central portion 145C-1 of the first channel structure 145-1.

In an embodiment, each of the first-1 extension portions 145E1-1 of the first channel structure 145-1 may have a first thickness in the third direction D3, each of the second-1 extension portions 145E2-1 of the first channel structure 145-1 may have a second thickness in the third direction D3, and the first central portion 145C-1 of the first channel structure 145-1 may have a third thickness in the third direction D3. In an embodiment, the third thickness may be greater than the first thickness and the second thickness.

In an embodiment, the first-1 extension portions 145E1-1 of the first channel structure 145-1 may be disposed at substantially the same level as the second-1 extension portions 145E2-1, respectively, of the first channel structure 145-1.

Other channel structures 145 except for the first channel structure 145-1 may have the same structure as that of the first channel structure 145-1, and thus repeated explanations are omitted herein. Each of the channel structures 145 or the first channel structure 145-1 may be an application of one of the channel structures 40 shown in FIGS. 1, 7, 10 and 11, and thus repeated explanations thereof are omitted herein.

Each of the channel structures 145 may include channel patterns 125 sequentially stacked in the third direction D3 on the insulation layer 105. In an embodiment, each of the channel structures 145 may include a plurality of channel patterns 125. For example, each of the channel structures 145 may include two to nine channel patterns 125, preferably, two to three channel patterns 125.

The gate structure 300 may extend in the second direction D2 on the insulation layer 105. The gate structure 300 may include a gate insulation pattern 270, a gate electrode 280 and a capping pattern 290.

In an embodiment, the gate structure 300 may at least partially cover the central portions 145C of the channel structures 145. In an embodiment, the gate structure 300 may cover lower and upper surfaces and opposite sidewalls in the second direction D2 of the central portions 145C of the channel structures 145.

In an embodiment, the gate insulation pattern 270 may be disposed on a surface of each of the channel structures 145, an upper surface of the insulation layer 105, and inner sidewalls of the first and second spacers 180 and 185. The gate electrode 280 may fill a space between the channel structures 145 spaced apart from each other in the third direction D3, between a lowermost one of the channel structures 145 and the insulation layer 105, and between the first gate spacers 180 spaced apart from each other in the first direction D1 on an uppermost one of the channel structures 145. The capping pattern 290 may contact upper surfaces of the gate insulation pattern 270 and the gate electrode 280 and may also contact inner sidewalls of the first gate spacers 180.

The gate insulation pattern 270 may include silicon oxide, a low-k dielectric material having a dielectric constant lower than that of silicon oxide, or a high-k dielectric material, e.g., hafnium oxide, zirconium, oxide, or the like. The gate electrode 280 may include a metal, e.g., titanium, platinum, ruthenium, gold, silver, molybdenum, aluminum, tungsten, copper, or the like, a conductive nitride, e.g., titanium nitride, tungsten nitride, tantalum nitride, or the like, or a conductive oxide, e.g., InZnO, AlZnO, or the like. The capping pattern 290 may include an insulating nitride, e.g., silicon nitride.

The first gate spacer 180 may be disposed on each of opposite sidewalls in the first direction D1 of the gate structure 300. The second gate spacers 185 may be disposed between the channel structures 145 neighboring in the third direction D3, and on each of opposite sidewalls in the first direction D1 of a portion of the gate structure 300 between the lowermost one of the channel structures 145 and the insulation layer 105.

Each of the first and second gate spacers 180 and 185 may include an oxide, e.g., silicon oxide, or an insulating nitride, e.g., silicon nitride.

The source contact structure 320 may be disposed on a portion of the insulation layer 105 adjacent to the gate structure 300 and may cover the lower and upper surfaces and the sidewalls of the first extension portions 145E1 of the channel structures 145. An upper portion of the source contact structure 320 may at least partially contact an outer sidewall of the first gate spacer 180.

The drain contact structure 340 may be disposed on a portion of the insulation layer 105 adjacent to the gate structure 300 and may cover the lower and upper surfaces and the sidewalls of the second extension portions 145E2 of the channel structures 145. An upper portion of the drain contact structure 340 may at least partially contact an outer sidewall of the first gate spacer 180.

The insulating interlayer 360 may be disposed on the insulation layer 105 and may cover sidewalls of the first gate spacer 180, the source contact structure 320 and the drain contact structure 340.

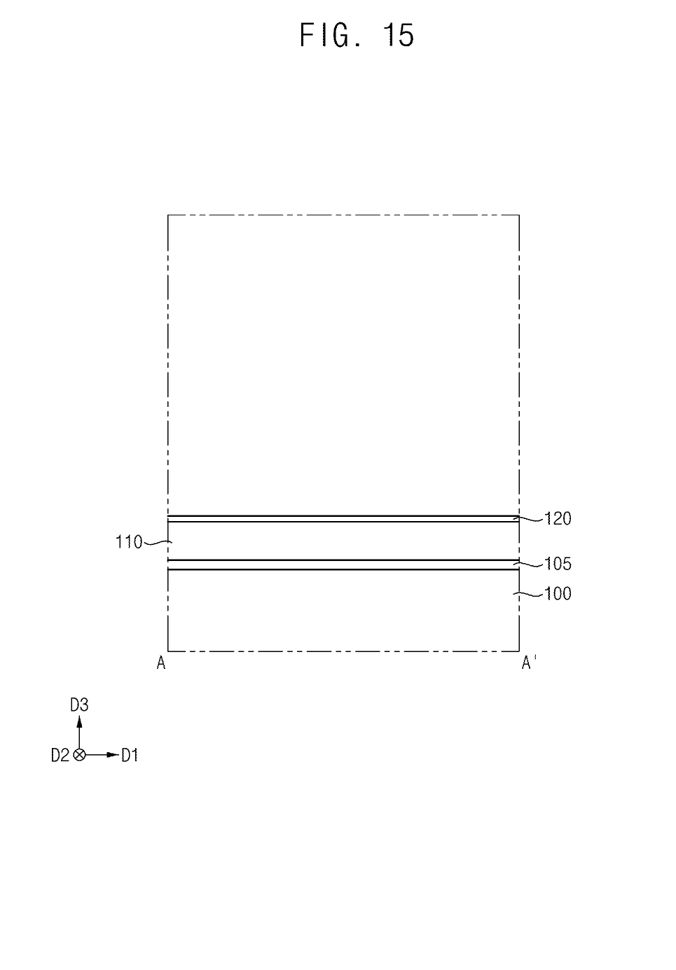

FIGS. 15 to 29 are perspective view and cross-sectional views illustrating a method of manufacturing a semiconductor device in accordance with an embodiment.

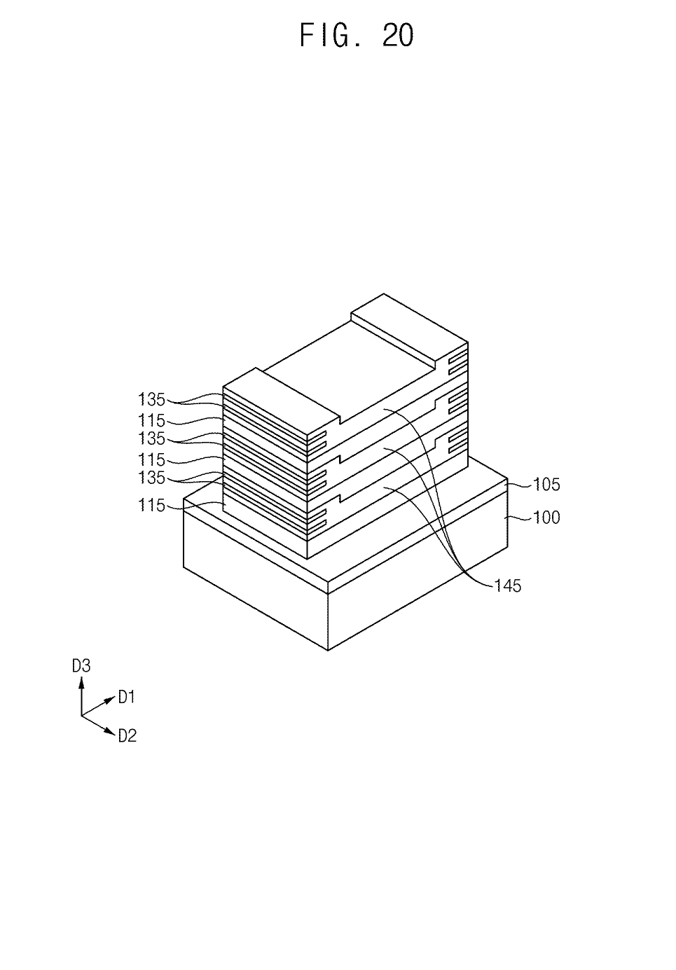

Particularly, FIGS. 15-19, 21, 23, 25, 27 and 29 are the cross-sectional views, and FIGS. 20, 22, 24, 26 and 28 are the perspective views.

Referring to FIG. 15, an insulation layer 105 may be formed on a substrate 100, and a first sacrificial layer 110 may be formed on the insulation layer 105.

A channel layer 120 may be formed on the first sacrificial layer 110.

The first sacrificial layer 110 may include a material having an etching selectivity with respect to the insulation layer 105 and the channel layer 120. The first sacrificial layer 110 may include, e.g., silicon-germanium.

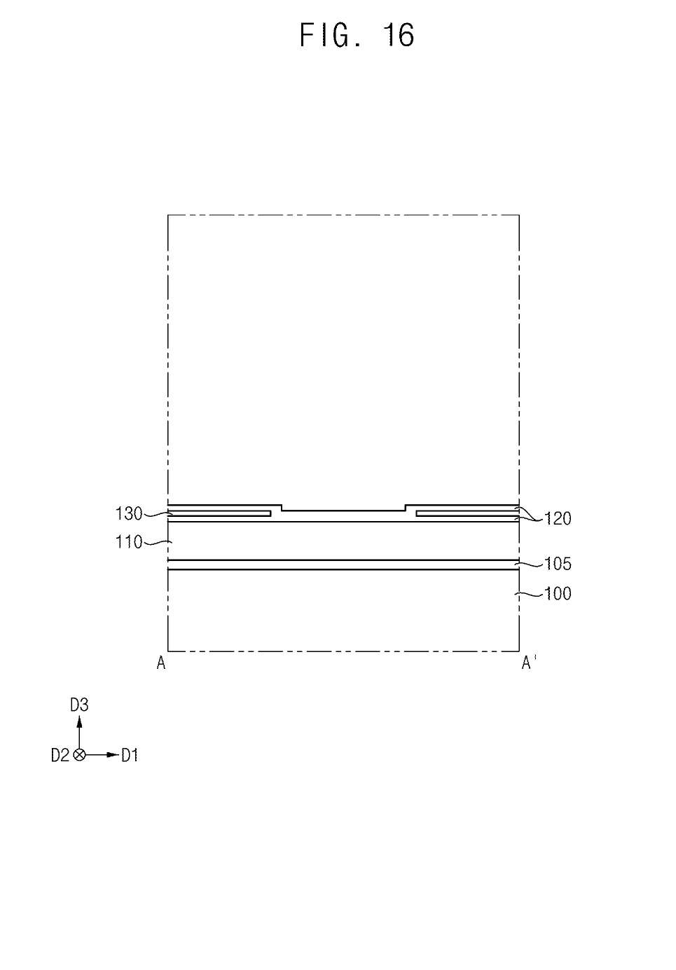

Referring to FIG. 16, a second sacrificial layer 130 may be formed on the channel layer 120, and the second sacrificial layer 130 may be patterned to partially expose an upper surface of the channel layer 120.

The channel layer 120 may be further formed on the second sacrificial layer 130 and the exposed upper surface of the channel layer 120.

The second sacrificial layer 130 may include a material having an etching selectivity with respect to the channel layer 120. The second sacrificial layer 130 may include, e.g., silicon-germanium.

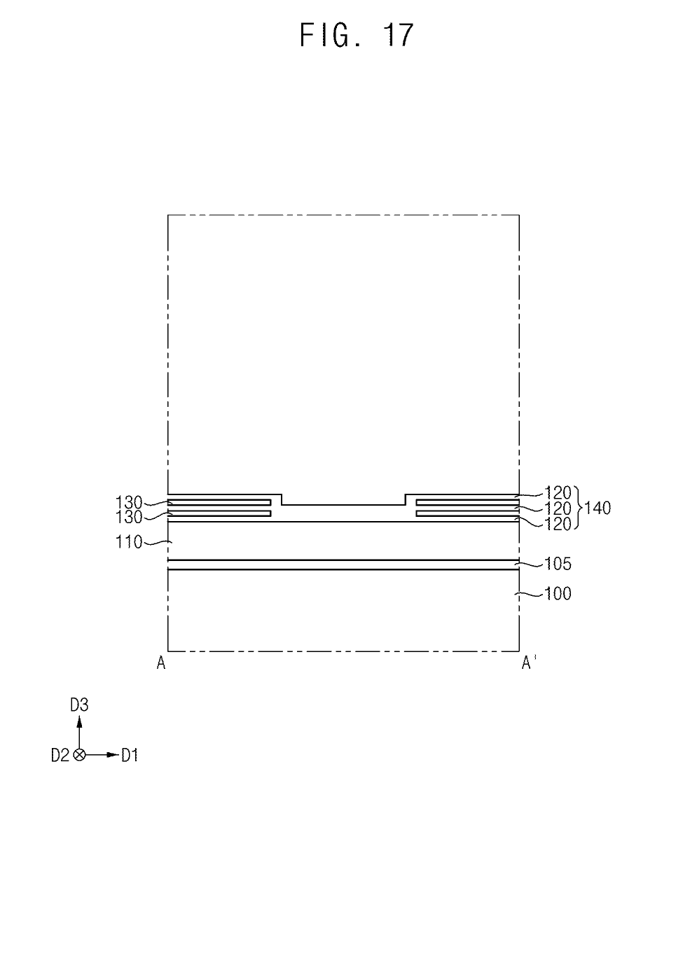

Referring to FIG. 17, processes substantially the same as or similar to those illustrated with reference to FIG. 16 may be performed again.

Thus, additional channel layers 120 may be sequentially stacked on a central portion of the channel layer 120, and additional channel layers 120 and additional second sacrificial layers 130 may be alternately and repeatedly formed on the second sacrificial layer 130.

The channel layers 120 stacked on the first sacrificial layer 110 in the third direction D3 may form a channel layer structure 140. FIG. 17 shows that the channel layer structure 140 includes three channel layers 120, however the present disclosure is not limited thereto. For example, the channel layer structure 140 may include more than two or three channel layers 120.ce

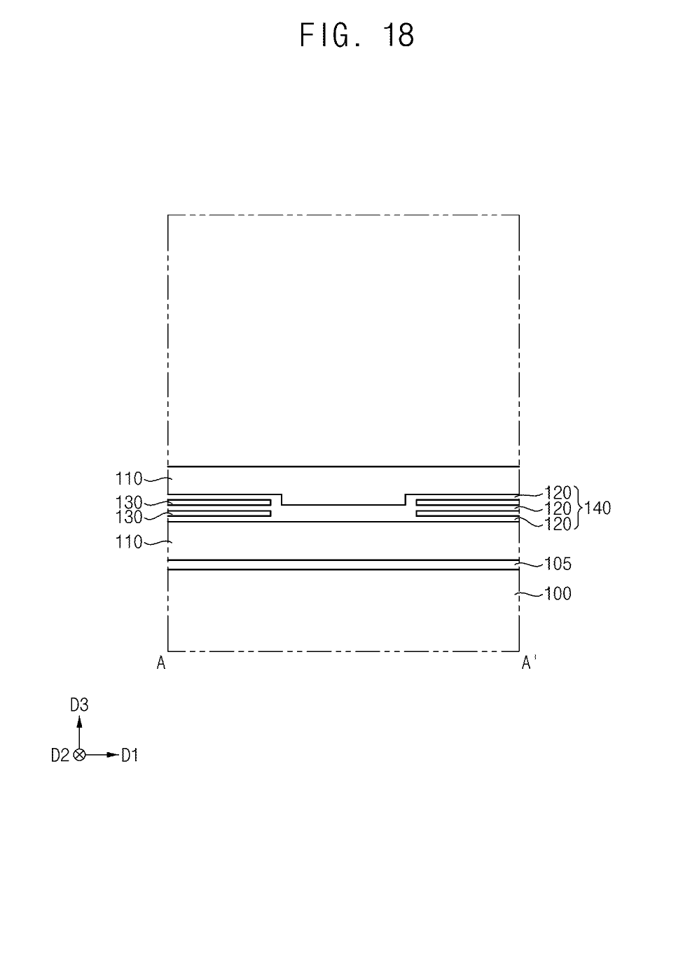

Referring to FIG. 18, an additional first sacrificial layer 110 may be formed on the channel layer structure 140, and a planarization process may be performed on the additional first sacrificial layer 110.

The planarization process may include a chemical mechanical polishing (CMP) process and/or an etch back process.

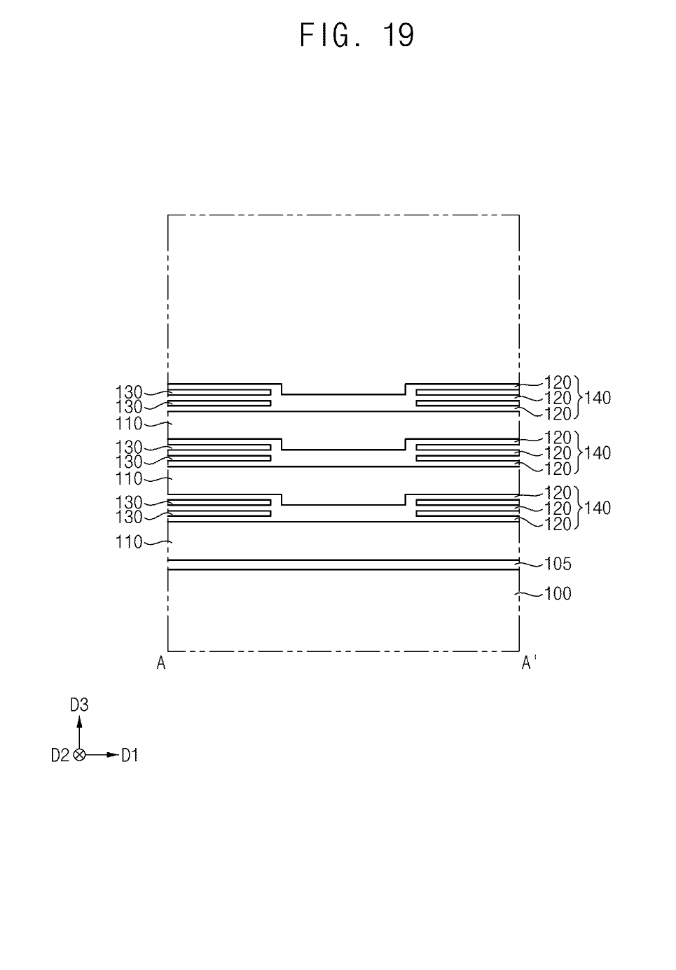

Referring to FIG. 19, processes substantially the same as or similar to those illustrated with reference to FIGS. 15-18 may be performed.

Thus, the first sacrificial layers 110 and the channel structures 140 may be alternately and repeatedly stacked in the third direction D3.

Hereinafter, the first sacrificial layers 110 together with the channel layer structures 140 may be referred to as a mold layer structure.

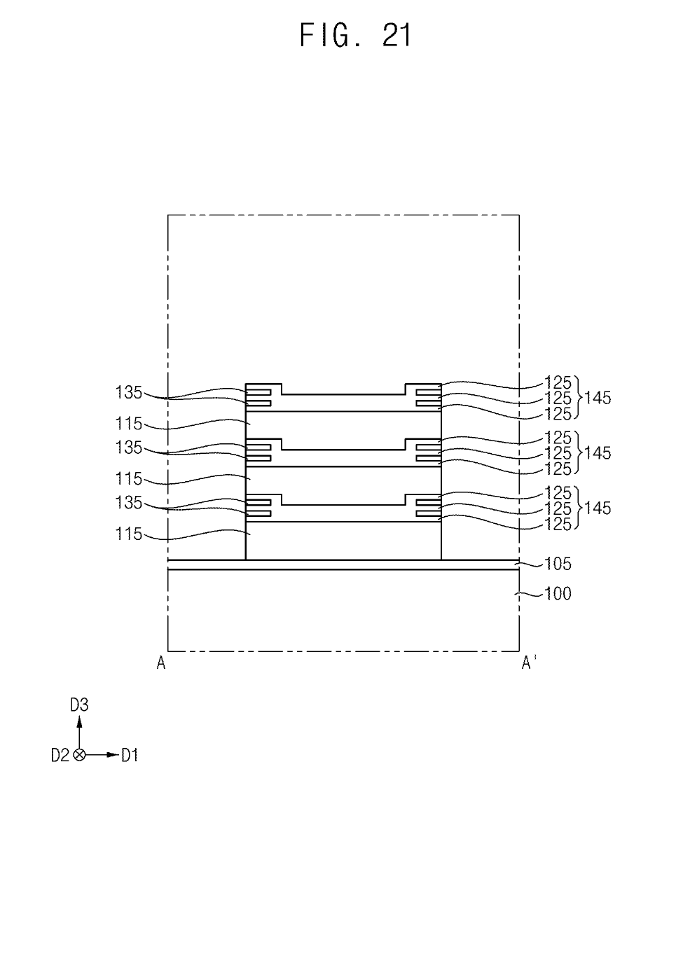

Referring to FIGS. 20 and 21, the mold layer structure may be patterned to form a stack structure.

The stack structure may include channel structures 145 and first sacrificial patterns 115 alternately and repeatedly stacked in the third direction D3.

Each of the channel structures 145 may include channel patterns 125 sequentially stacked in the third direction D3.

In each of the channel structures 145, a second sacrificial pattern 135 may remain between the channel patterns 125 neighboring in the third direction D3. Thus, in each of the channel structures 145, end portions in the first direction D1 of the channel patterns 125 may be spaced apart from each other in the third direction D3 by the second sacrificial patterns 135.

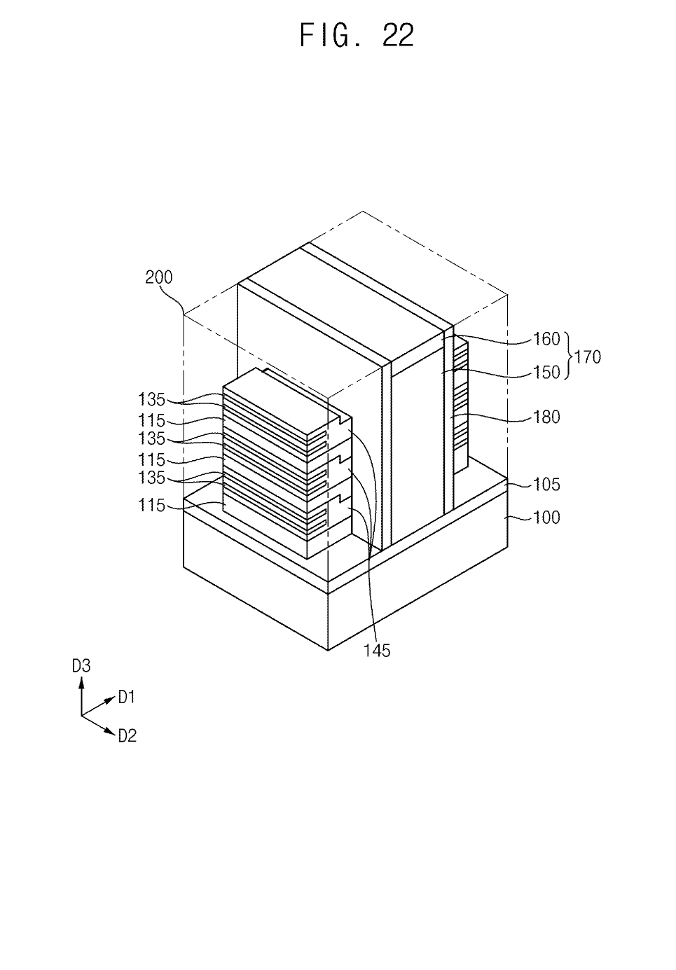

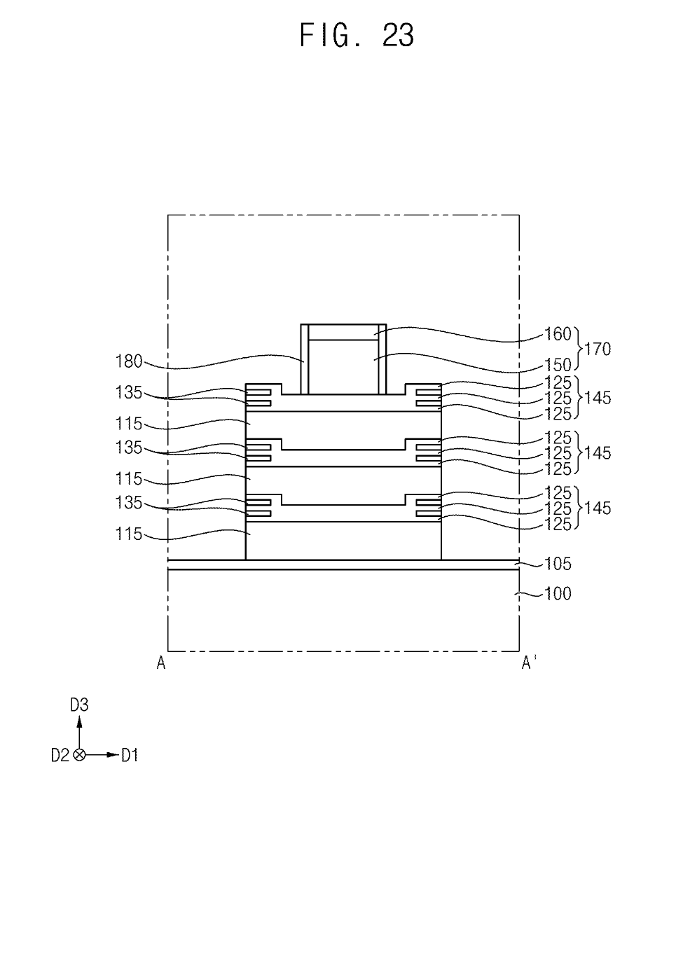

Referring to FIGS. 22 and 23, a dummy gate electrode layer and a dummy gate mask layer may be formed on the substrate 100 to cover the stack structure and the insulation layer 105, an etching mask extending in the second direction D2 may be formed on the dummy gate mask layer, and the dummy gate mask layer may be patterned by an etching process using the etching mask to form a dummy gate mask 160.

The dummy gate electrode layer may be patterned using the dummy gate mask 160 as an etching mask to form a dummy gate electrode 150. The dummy gate electrode 150 may include a material having an etching selectivity with respect to the channel structures 145. For example, the dummy gate electrode 150 may include polysilicon.

The dummy gate electrode 150 and the dummy gate mask 160 sequentially stacked on the insulation layer 105 may collectively form a dummy gate electrode 170. In an embodiment, the dummy gate electrode 170 may extend in the second direction D2 and may cover opposite sidewalls in the second direction D2 of the stack structure.

A first gate spacer 180 may be formed on each of opposite sidewalls in the first direction D1 of the dummy gate structure 170.

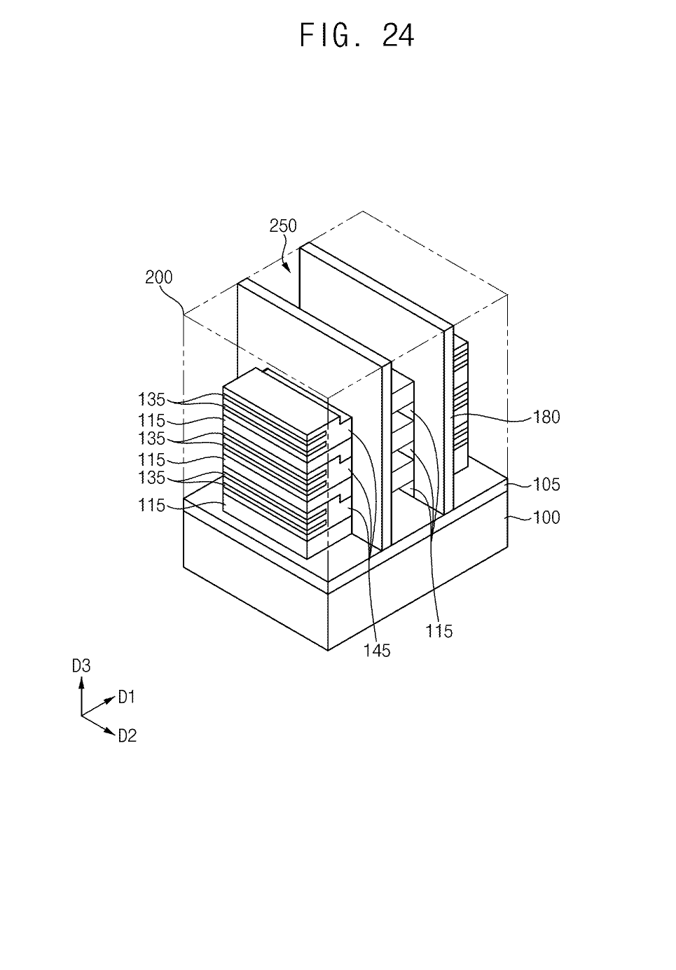

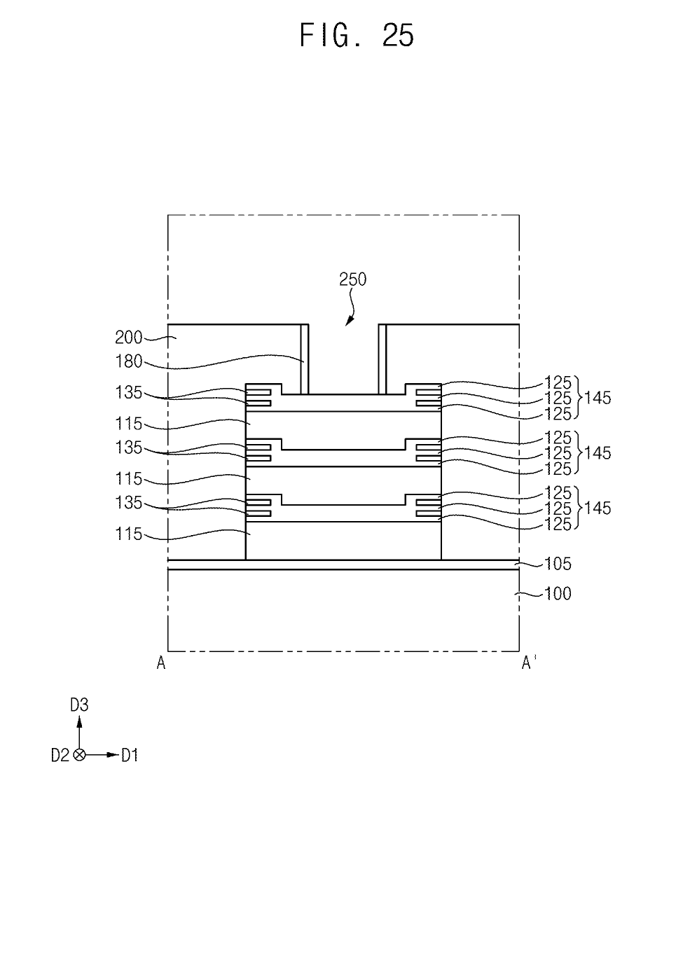

Referring to FIGS. 24 and 25, a third sacrificial layer 200 may be formed on the insulation layer 105, the stack structure and the dummy gate structure 170.

The third sacrificial layer 200 may include a material having an etching selectivity with respect to the insulation layer 105, the channel structures 145 and the first gate spacer 180. The third sacrificial layer 200 may include, e.g., silicon nitride, silicon oxynitride, silicon oxycarbide, silicon boronitride, silicon boron carbonitride, silicon oxycarbonitride, or the like.

A planarization process may be performed until an upper surface of the dummy gate electrode 150 is exposed to remove an upper portion of the third sacrificial layer 200, an upper portion of the first gate spacer 180 and the dummy gate mask 160 of the dummy gate structure 170.

The dummy gate electrode 150 and the first sacrificial patterns 115 may be removed by, e.g., a wet etching process and/or a dry etching process.

Thus, a first opening 250 may be formed to expose an inner sidewall of the first gate spacer 180, surfaces of the channel structures 145, sidewalls of the first sacrificial patterns 115 and the upper surface of the insulation layer 105.

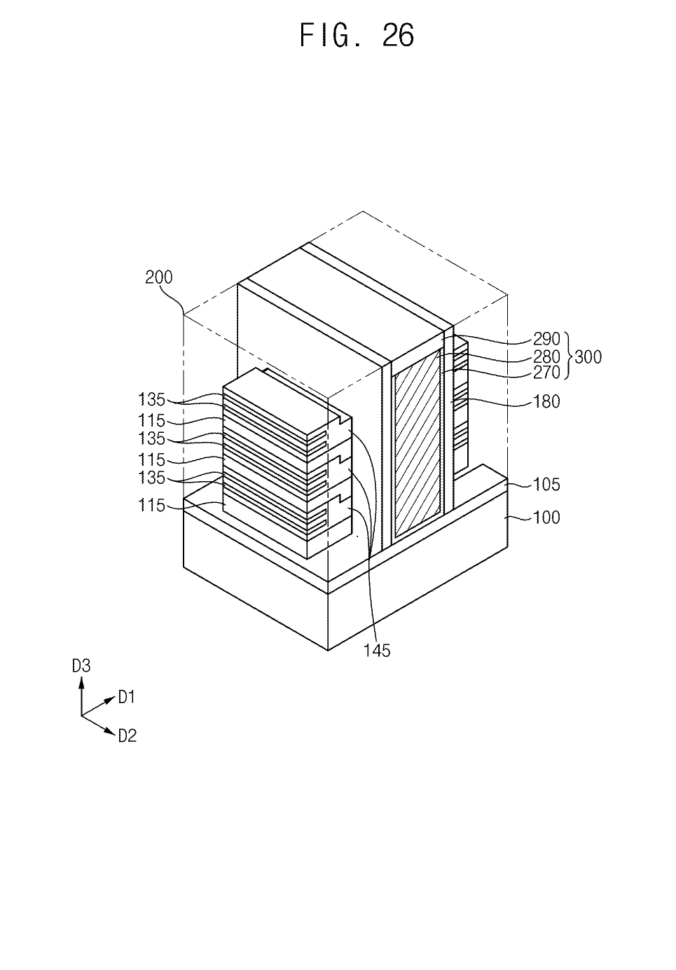

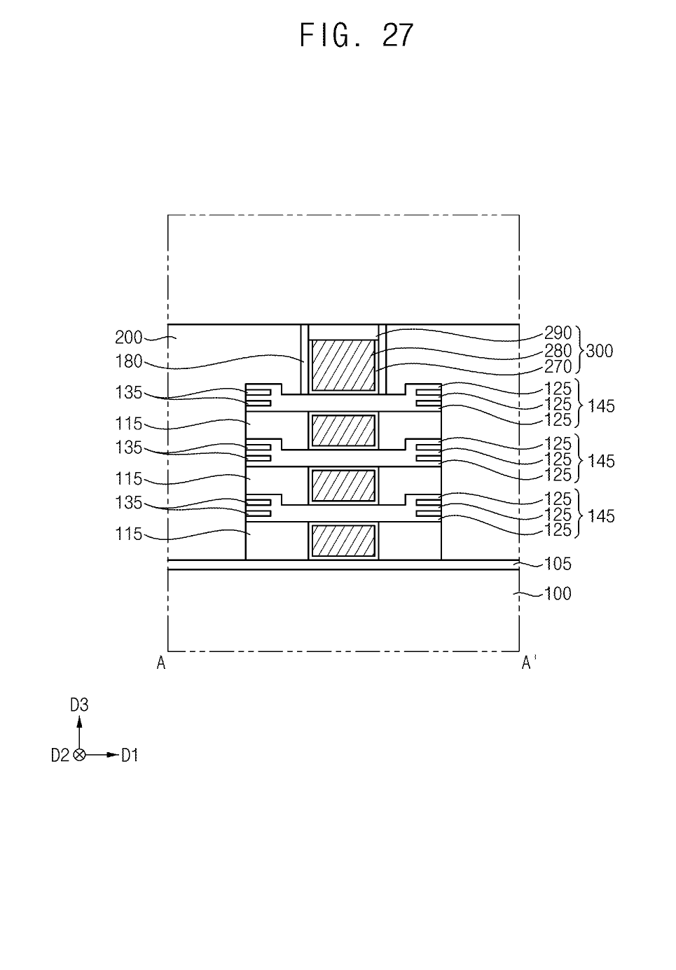

Referring to FIGS. 26 and 27, a gate insulation layer may be formed on the inner sidewall of the first gate spacer 180, the surfaces of the channel structures 145, the sidewalls of the first sacrificial patterns 115, the upper surface of the insulation layer 105 and an upper surface of the third sacrificial layer 200, and a gate electrode layer may be formed on the gate insulation layer to fill a remaining portion of the first opening 250.

A planarization process may be performed on the gate electrode layer and the gate insulation layer until the upper surface of the third sacrificial layer 200 is exposed to form a gate electrode 280 and a gate insulation pattern 270 in the first opening 250. Upper portions of the gate insulation pattern 279 and the gate electrode 280 may be removed to form a first recess, and a capping pattern 290 may be formed in the first recess. Thus, a gate structure 300 including the gate insulation pattern 270, the gate electrode 280 and the capping pattern 290 may be formed.

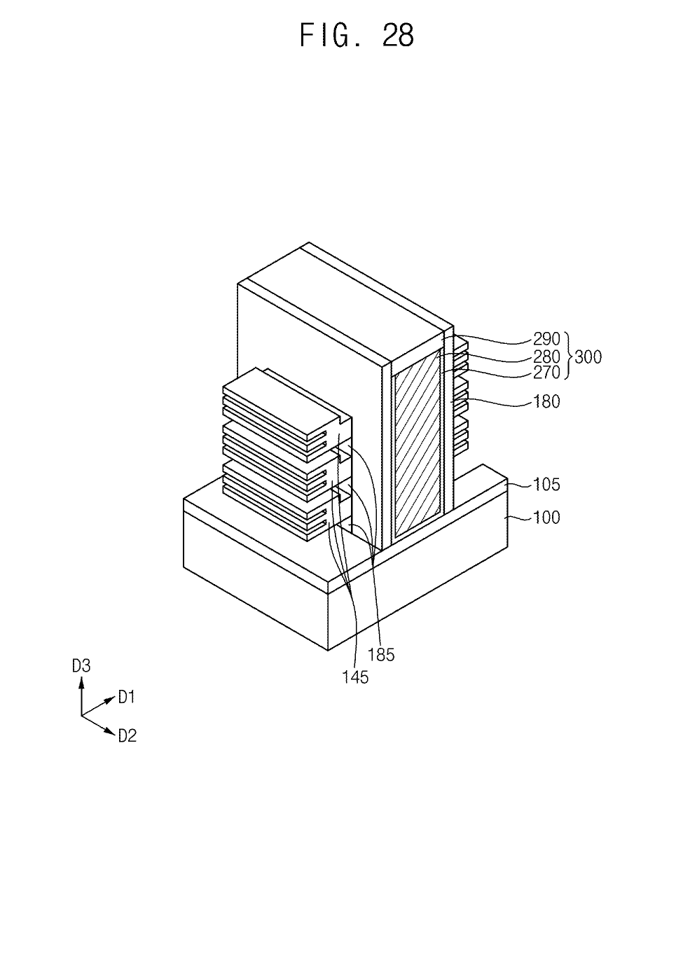

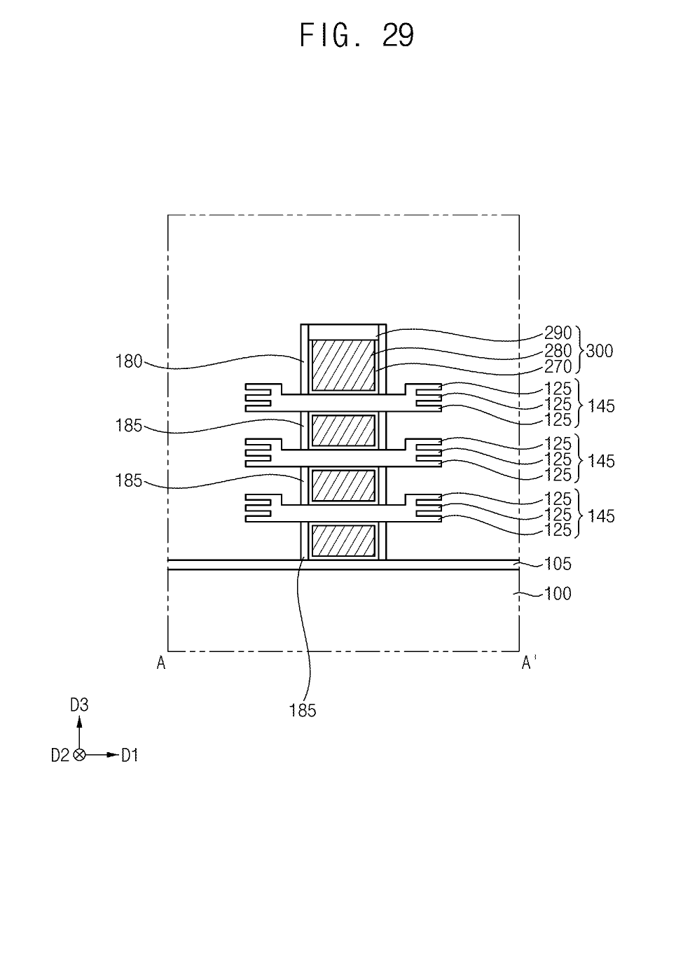

Referring to FIGS. 28 and 29, the third sacrificial layer 200 may be removed by an etching process.

During the etching process, sidewalls of opposite end portions in the first direction D1 of the channel patterns 125 included in each of the channel structures 145 and sidewalls of the first and second sacrificial patterns 115 and 135 may be exposed.

The first and second sacrificial patterns 115 and 135 may be removed. Thus, lower and upper surfaces of the end portions in the first direction D1 of the channel patterns 125 included in each of the channel structures 145 and a surface of the gate insulation pattern 270 may be exposed.

A second gate spacer 185 may be formed to cover the exposed surface of the gate insulation pattern 270. In an embodiment, an outer sidewall in the first direction D1 of the second gate spacer 185 may be aligned with an outer sidewall of the first gate spacer 180 in the third direction D3, however, the present disclosureis not limited thereto. For example, the outer sidewall in the first direction D1 of the second gate spacer 185 may be offset inwardly or outwardly to the outer sidewall of the first gate spacer 180 in the third direction D3.

Referring to FIGS. 12-14 again, a source contact structure 320 covering the lower and upper surfaces and the sidewalls of first end portions in the first direction D1 of the channel patterns 125 of the channel structures 145, a drain contact structure 340 covering the lower and upper surfaces and the sidewalls of second end portions in the first direction D1 of the channel patterns 125 of the channel structures 145, and an insulating interlayer 360 covering the source contact structure 320 and the drain contact structure 340 may be formed.

In an embodiment, a fourth metal layer may be formed on the insulation layer 105, the channel structures 145 and the gate structure 300, the fourth metal layer may be patterned to form the source contact structure 320 and the drain contact structure 340, and the insulating interlayer 360 may be formed to cover the source contact structure 320 and the drain contact structure 340.

Alternatively, the insulating interlayer 360 may be formed on the substrate 100 to cover the insulation layer 105, the channel structures 145 and the gate structure 300, an etching process may be performed on the insulating interlayer 360 to form second and third openings exposing the first and second end portions of the channel patterns 125 of the channel structures 145, and the source contact structure 320 and the drain contact structure 340 may be formed in the second and third openings, respectively.

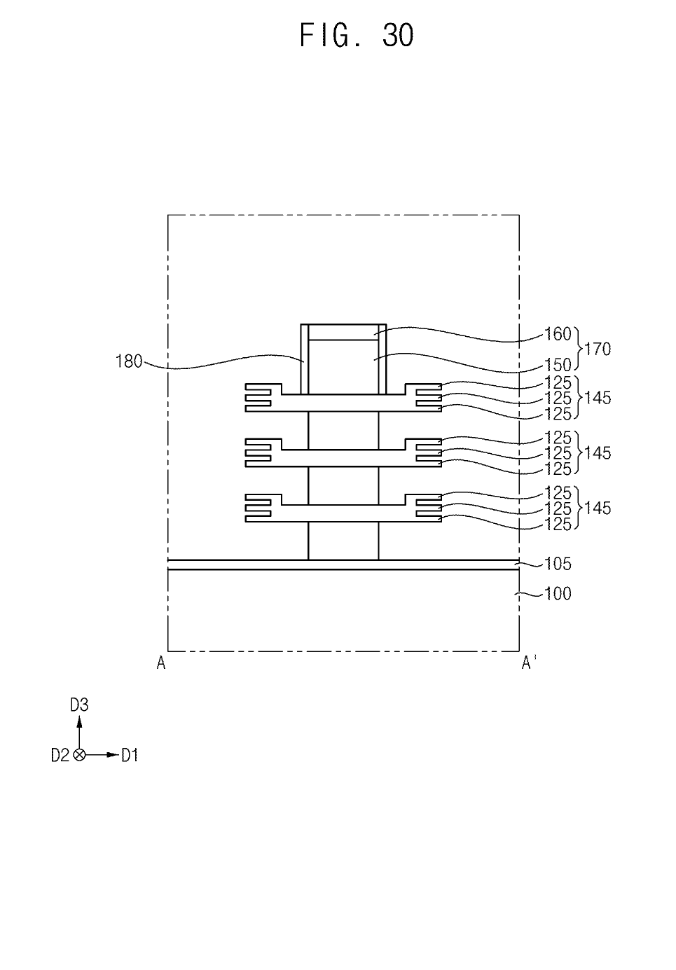

FIGS. 30-32 are cross-sectional views illustrating a method of manufacturing a semiconductor device in accordance with an embodiment. This method may include processes substantially the same as or similar to those illustrated with reference to FIGS. 12-29, and thus repeated explanations thereof are omitted herein.

Referring to FIG. 30, after performing the processes illustrated with reference to FIGS. 15-23, before forming the gate structure 300 in the first opening 250 that may be formed by removing the dummy gate structure 170, opposite end portions in the first direction D1 of the first sacrificial patterns 115 and the second sacrificial patterns 135 may be removed.

Thus, the lower and upper surfaces of the first and second end portions in the first direction D1 of the channel patterns 125 included in each of the channel structures 145 may be exposed.

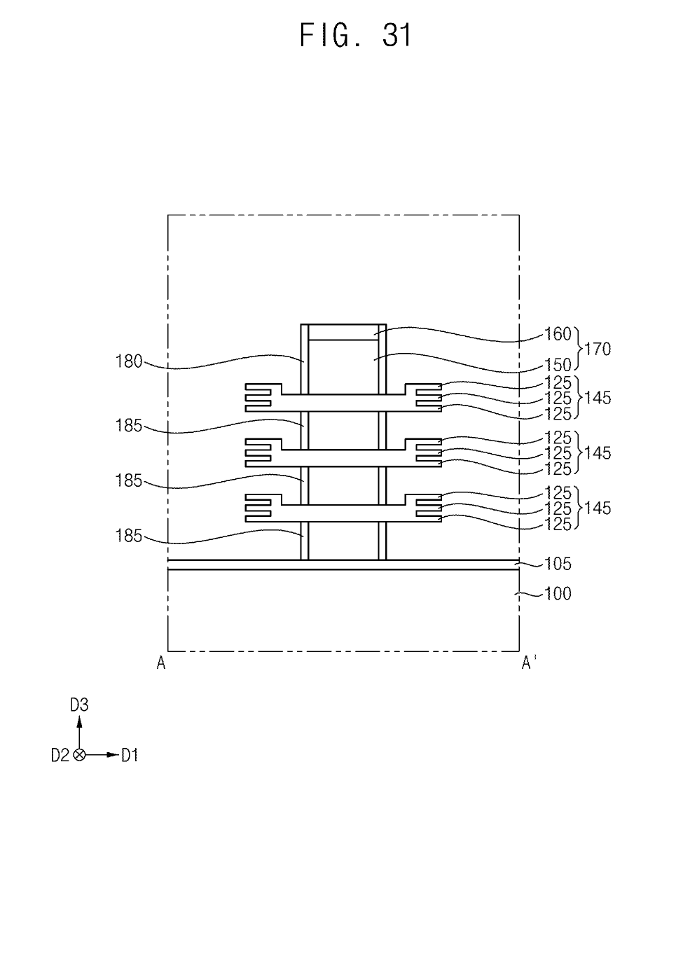

Referring to FIG. 31, the second gate spacer 185 may be formed on each of opposite sidewalls in the first direction D1 of each of the first sacrificial patterns 115.

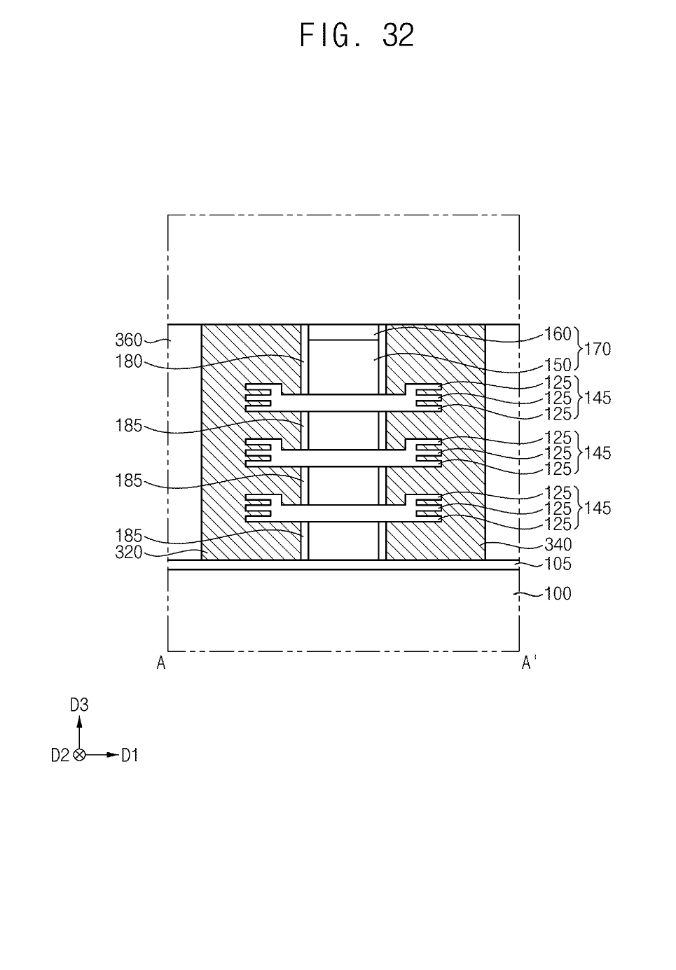

Referring to FIG. 32, processes substantially the same as or similar to those illustrated with reference to FIGS. 12-14 may be performed to form the source contact structure 320, the drain contact structure 340 and the insulating interlayer 360.

Processes substantially the same as or similar to those illustrated with reference to FIGS. 24-27 may be performed to form the gate structure 300, so that the semiconductor device may be fabricated.

In an embodiment, after replacing the dummy gate structure 170 with the gate structure 300, the source contact structure 320 and the drain contact structure 340 may be formed (refer to FIGS. 15-29 and 12-14). Alternatively, after forming the source contact structure 320 and the drain contact structure 340, the dummy gate structure 170 may be replaced with the gate structure 300 (refer to FIGS. 30-32).

In the method of manufacturing the semiconductor device in accordance with an embodiment, a first channel pattern may be formed on a substrate. A first source contact pattern and a first drain contact pattern may be formed to cover upper surfaces of first and second ends, respectively, of the first channel pattern in a first direction parallel to an upper surface of the substrate. A second channel pattern may be formed to cover an upper surface and a sidewall of the first source contact pattern, an upper surface of a central portion in the first direction of the first channel pattern, and an upper surface and a sidewall of the first drain contact pattern. A second source contact pattern and a second drain contact pattern covering upper surfaces of first and second ends, respectively, of the second channel pattern in the first direction may be formed. Each of the first and second channel patterns may include a two-dimensional semiconductor material.

In an embodiment, each of the first and second channel patterns may include a transition metal dichalcogenide (TMD).

In an embodiment, each of the first and second source contact patterns and each of the first and second drain contact patterns may include at least one of gold, palladium, niobium, nickel, cobalt, scandium, yttrium, vanadium, hafnium, zirconium, tantalum, aluminum, indium, copper, or zinc.

In an embodiment, the upper surface and a sidewall of the first end of the first channel pattern in the first direction may be covered by the first source contact pattern, the upper surface and a sidewall of the second end of the first channel pattern in the first direction may be covered by the first drain contact pattern, the upper surface, a lower surface and a sidewall of the first end of the second channel pattern in the first direction may be covered by the first and second source contact patterns, and the upper surface, a lower surface and a sidewall of the second end of the second channel pattern in the first direction may be covered by the first and second drain contact patterns.

In an embodiment, a third channel pattern may be formed to cover an upper surface and a sidewall of the second source contact pattern, an upper surface of a central portion in the first direction of the second channel pattern, and an upper surface and a sidewall of the second drain contact pattern. A third source contact pattern and a third drain contact pattern may be formed to cover upper surfaces of first and second ends, respectively, in the first direction of the third channel pattern.

In an embodiment, the upper surface, a lower surface and a sidewall of the first end in the first direction of the third channel pattern may be covered by the second and third source contact patterns, and the upper surface, a lower surface and a sidewall of the second end in the first direction of the third channel pattern may be covered by the second and third drain contact patterns.

In an embodiment, each of the first and second channel patterns may have a single-layered structure or a multi-layered structure.

The foregoing is illustrative of embodiments of the present disclosure and is not to be construed as limiting thereof. Although a few embodiments of the present disclosure have been described, those skilled in the art will readily appreciate that many modifications are possible in the an embodiments of the present disclosure without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various embodiments of the present disclosure and is not to be construed as limited to the specific example embodiments disclosed, and that modifications to the disclosed example embodiments, as well as other embodiments of the present disclosure, are intended to be included within the scope of the appended claims.

What is claimed is:

1. A semiconductor device, comprising:
a channel structure on a substrate, the channel structure including a two-dimensional semiconductor material, and the channel structure including:
a central portion extending in a first direction parallel to an upper surface of the substrate;
first extension portions spaced apart from each other in a vertical direction perpendicular to the upper surface of the substrate, each of the first extension portions extending in the first direction from a first end in the first direction of the central portion; and
second extension portions spaced apart from each other in the vertical direction, each of the second extension portions extending in the first direction from a second end in the first direction of the central portion;
a source contact structure covering lower and upper surfaces and a sidewall of each of the first extension portions of the channel structure; and
a drain contact structure covering lower and upper surfaces and a sidewall of each of the second extension portions of the channel structure.

2. The semiconductor device as claimed in claim 1, wherein the two-dimensional semiconductor material includes transition metal dichalcogenide (TMD).

3. The semiconductor device as claimed in claim 1, wherein each of the source contact structure and the drain contact structure includes at least one of gold, palladium, niobium, nickel, cobalt, scandium, yttrium, vanadium, hafnium, zirconium, tantalum, aluminum, indium, copper, or zinc.

4. The semiconductor device as claimed in claim 1, wherein an upper surface of an uppermost one of the first extension portions of the channel structure and an upper surface of an uppermost one of the second extension portions of the channel structure are higher than an upper surface of the central portion of the channel structure.

5. The semiconductor device as claimed in claim 4, wherein a lower surface of a lowermost one of the first extension portions of the channel structure and a lower surface of a lowermost one of the second extension portions of the channel structure are higher than a lower surface of the central portion of the channel structure.

6. The semiconductor device as claimed in claim 1, wherein:
each of the first extension portions of the channel structure has a first width in the vertical direction,
each of the second extension portions of the channel structure has a second width in the vertical direction,
the central portion of the channel structure has a third width in the vertical direction, and
the third width is greater than the first width and the second width.\

7. The semiconductor device as claimed in claim 1, wherein the first extension portions and the second extension portions of the channel structure are disposed at the same levels.

8. The semiconductor device as claimed in claim 1, further comprising a gate structure on the channel structure.

9. A semiconductor device, comprising:
first channel pattern on a substrate;
a first source contact pattern and a first drain contact pattern covering upper surfaces of first and second ends, respectively, of the first channel pattern in a first direction parallel to an upper surface of the substrate;
a second channel pattern covering an upper surface and a sidewall of the first source contact pattern, and upper surface of a central portion in the first direction of the first channel pattern, and an upper surface and a sidewall of the first drain contact pattern; and
a second source contact pattern and a second drain contact pattern covering upper surfaces of first and second ends, respectively, of the second channel pattern in the first direction,
wherein each of the first and second channel patterns includes a two-dimensional semiconductor material.

10. The semiconductor device as claimed in claim 9, wherein each of the first and second channel patterns includes transition metal dichalcogenide (TMD).

11. The semiconductor device as claimed in claim 9, wherein each of the first and second source contact patterns and each of the first and second drain contact patterns include at least one of gold, palladium, niobium, nickel, cobalt, scandium, yttrium, vanadium, hafnium, zirconium, tantalum, aluminum, indium, copper, or zinc.

12. The semiconductor device as claimed in claim 9, wherein the upper surface and a sidewall of the first end of the second channel pattern in the first direction are covered by the first and second source contact patterns, and the upper surface and a sidewall of the second end of the second channel pattern in the first direction are covered by the first and second drain contact patterns.

13. The semiconductor device as claimed in claim 12, further comprising:
a third channel pattern covering an upper surface and a sidewall of the second source contact pattern, an upper surface of a central portion in the first direction of the second channel pattern, and an upper surface and a sidewall of the second drain contact pattern; and
a third source contact pattern and a third drain contact pattern covering upper surfaces of first and second ends, respectively, in the first direction of the third channel pattern.

14. The semiconductor device as claimed in claim 13, wherein an upper surface, a lower surface and a sidewall of the first end in the first direction of the third channel pattern is covered by the second and third source contact patterns, and an upper surface, a lower surface and a sidewall of the second end in the first direction of the third channel pattern is covered by the second and third source contact patterns.

15. A semiconductor device, comprising:
channel structures on a substrate, the channel structures being spaced apart from each other in a vertical direction perpendicular to an upper surface of the substrate, and each of the channel structures including a two-dimensional semiconductor material and including:
a central portion in a first direction parallel to the upper surface of the substrate;
first extension portions spaced apart from each other in the vertical direction, each of the first extension portions extending in the first direction from a first end in the first direction of the central portion; and
second extension portions spaced apart from each other in the vertical direction, each of the second extension portions extending in the first direction from a second end in the first direction of the central portion;
a gate structure on the substrate, the gate structure extending in a second direction parallel to the upper surface of the substrate and crossing the first direction and at least partially covering the central portion of each of the channel structures;
a source contact structure covering lower and upper surfaces and a sidewall of each of the first extension portions of each of the channel structures; and
a drain contact structure covering lower and upper surfaces and a sidewall of each of the second extension portions of each of the channel structures,
wherein a first channel structure among the channel structures includes:
a first central portion;
first-1 extension portions, each of the first-1 extension portions extending in the first direction from a first end in the first direction of the first central portion; and
second-1 extension portions, each of the second-1 extension portions extending in the first direction from a second end in the first direction of the first central portion.

16. The semiconductor device as claimed in claim 15, wherein each of the channel structures includes transition metal dichalcogenide (TMD).

17. The semiconductor device as claimed in claim 15, wherein each of the source contact structure and the drain contact structure includes at least one of gold, palladium, niobium, nickel, cobalt, scandium, yttrium, vanadium, hafnium, zirconium, tantalum, aluminum, indium, copper, or zinc.

18. The semiconductor device as claimed in claim 15, wherein an upper surface of an uppermost one of the first-1 extension portions of the first channel structure and an upper surface of an uppermost one of the second-1 extension portions of the first channel structure is higher than an upper surface of the first central portion of the first channel structure.

19. The semiconductor device as claimed in claim 15, wherein each of the first-1 extension portions of the first channel structure has a first thickness in the vertical direction, each of the second-1 extension portions of the first channel structure has a second thickness in the vertical direction, and the first central portion of the first channel structure has a third thickness in the vertical direction, and
wherein the third thickness is greater than the first thickness and the second thickness.

20. The semiconductor device as claimed in claim 15, wherein the first-1 extension portions of the first channel structure and the second-1 extension portions of the first channel structure are disposed at the same levels, respectively.
